(19) United States
(12) Patent Application Publication
(10) Pub. No.: US 2021/0111346 A1
(43) Pub. Date: Apr. 15, 2021

(54) CONJUGATED POLYMERS WITH MULTISTAGE SIDE-CHAIN CLEAVAGE

(71) Applicant: GEORGIA TECH RESEARCH CORPORATION, Atlanta, GA (US)

(72) Inventors: JOHN ROBERT REYNOLDS, DUNWOODY, GA (US); BRIAN J. SCHMATZ, ATLANTA, GA (US)

(21) Appl. No.: 16/498,799

(22) PCT Filed: Mar. 30, 2018
(86) PCT No.: PCT/US18/25401

§ 371 Date: Sep. 27, 2019

Related U.S. Application Data
(60) Provisional application No. 62/479,012, filed on Mar. 30, 2017.

(51) Int. Cl. H01L 51/00; C08G 61/12; C09D 5/24; C09D 165/00; C09D 11/52; C09D 11/102; C09D 11/30

(52) U.S. Cl. CPC H01L 51/0036; H01L 51/0545; C09D 5/24; C09D 165/00; C09D 11/52; C09D 11/102; C09D 11/30; H01L 51/0043; C08G 2261/124; C08G 2261/148; C08G 2261/143; C08G 2261/1426; C08G 2261/1424; C08G 2261/18; C08G 2261/3223; C08G 2261/3243; C08G 2261/3241; C08G 2261/414; C08G 2261/514; C08G 2261/92; H01L 51/0003; C08G 61/126

(57) ABSTRACT

Multistage side-chain conjugated polymers (CPs) have a conjugated backbone from a multiplicity of repeating unit where at least one of the repeating units has a multistage side-chain. The repeating unit has a conjugated backbone portion and a multistage side-chain, which has one or more responsive functionalities. Responsive functionalities include a photo- or thermal-cleavable portion connected by a first linker between the backbone portion and the cleavable portion, and a chemically activatable solubilizing portion having an activatable functionality that can undergo a chemical reaction to provide aqueous solubility. The multistage side-chain CP is prepared in an organic solution and converted to an aqueous soluble activated multistage side-chain CP for deposited on a substrate. Upon cleavage, a multistage side-chain residue is liberated and removed from an insoluble core CP film that can be part of an organic electronic device.

### CROSS-REFERENCE TO A RELATED APPLICATION

This application claims the benefit of U.S. Provisional Application Ser. No. 62/479,012, filed Mar. 30, 2017, the disclosure of which is hereby incorporated by reference in its entirety, including all figures, tables and drawings.

This invention was made with government support under Grant No. N00014-14-1-0173 awarded by the Office of Naval Research. The government has certain rights in the invention.

### BACKGROUND OF INVENTION

From self-driving cars to robotics to home temperature control, the “Internet of Things” vision of seamless integration between the physical world and the digital world is rapidly becoming a reality. To fully achieve this vision, electronics components like transistors, sensors, and batteries must be made both commoditized and customizable. Currently, the printed electronics industry aims to provide these cheap, versatile electronics components by transitioning away from traditional high-energy silicon manufacturing and towards high throughput, solution based printing of organic materials. While printed electronics are beginning to meet performance metrics for select applications, the solvents used in the printing process are typically chlorinated, which carry risks associated with toxicity, volatility, and in the case of chlorobenzene, flammability. Not only are these solvents a risk to employees and the surrounding environment, but their use also carries financial burdens associated with their regulation and disposal.

To avoid these safety issues and costs, the polymers in electronic inks can be designed for aqueous printing, providing a safer and more sustainable method for printing electronics. It is estimated that current printing processes for organic photovoltaic (OPV) devices would require 16 million liters of chlorobenzene to print 1GWp of solar panels. Life Cycle Analysis on this process reveals that the thermal energy involved in the production of chlorobenzene alone would add 10 days to the energy payback time, whereas switching to water decreases that time to 4 hours.

While the motivation to print from water is clear, the methods for doing so are still in early development. Predominately, there have been three approaches to processing electroactive polymers from aqueous solutions: (1) depositing polymers with pendant ionic side-chains (sulfonates, carboxylates, ammoniums), (2) depositing polymers with polar nonionic side-chains (glycols, alcohols), and (3) depositing dispersions of polymer colloids using surfactants. Polymers with pedant ionic side-chains are commonly used as electrode modification materials, but are limited in semiconductor applications due to their conductivity in the neutral state and the propensity of ions to screen a voltage bias. Polar, nonionic side-chains, such as glymes, remedy effects of pendant ions and have been used to achieve water soluble thiophenes for OFETs with mobility in the order of 10⁵ cm²V⁻¹s⁻¹. However, these polymers are typically difficult to synthesize and purify using conventional methods. Polymer dispersions in aqueous solutions have led to the most promising results as polymers that are known to attain high mobility can be used. Polymers with an OFET hole mobility of ˜5 cm²V⁻¹s⁻¹ deposited from chlorobenzene could be deposited from water using the surfactant SDS to achieve ˜10⁻³ cm²V⁻¹s⁻¹ and nonionic surfactants to achieve up to 2.5 cm²V⁻¹s⁻¹. Although this method achieves promising mobility values, the deposition is mainly limited to drop-casting, as the polymer-surfactants can lead to wetting issues in roll-to-roll (R2R) type depositions.

These methods attempt to work within processing frameworks designed for organic soluble polymers with fixed solubilizing chains. Alternatively, materials can be designed to posses electronic functionality and processing functionality. For example, thermo-cleavable ester side-chains have been incorporated into conjugated polymers to increase device stability. These polymers are cast from chlorobenzene and heated to ˜200° C. to cleave ester side-chains to form carboxylic acids to leave polymers that operated with longer device lifetimes then their non-cleaved counterparts. In this system, long aliphatic chains solubilize the polymers and ester linkage provides processing functionality that allows for their removal after deposition. The market needs novel design guidelines for integrating processing functionality into conjugated polymers that enable aqueous processing in the production of organic electronic devices.

### BRIEF SUMMARY

Embodiments of the invention are directed to a multistage side-chain conjugated polymer (CP), comprising a conjugated backbone where the conjugated backbone comprising a multiplicity of at least one repeating unit where at least one of the repeating units has a conjugated backbone portion and a multistage side-chain. The repeating units may be of the same structure or of different structures. The multistage side-chain has one or more multiple responsive functionalities. The multistage side-chain has at least one photo-cleavable portion with a photolytically labile functionality or at least one thermal-cleavable portion with a thermally labile functionality. The multistage side-chain has at least one first linker of at least one bond that links the backbone portion to the photo-cleavable portion or thermal-cleavable portion. The multistage side-chain has at least one chemically activatable solubilizing portion that includes an activatable functionality capable of undergoing a chemical reaction to provide an aqueous solubilizing functionality bound to an activated multistage side-chain. The aqueous solubilizing functionality can be the photolytically labile functionality or the thermally labile functionality. Alternatively, the aqueous solubilizing functionality can be a separate functionality. When the aqueous solubilizing functionality is a separate functionality to the photolytically labile functionality or the thermally labile functionality, at least one second linker is present that is at least one bond links the solubilizing portion to the cleavable portion. The multistage side-chain CP can be sequentially: prepared in an organic solution comprising at least one organic solvent; converted to an aqueous soluble activated multistage side-chain CP, and photolytically or thermally cleaved to an insoluble core CP comprising the conjugated backbone portion.

The multistage side-chain CP can be a homopolymer or a copolymer with at least one first repeating unit comprising the conjugated backbone portion and the multistage side-chain and at least one second repeating unit comprising a conjugated backbone portion without the multistage side-chain. The photolytically labile functionality can be an o-nitrobenzyl group, a 9-phenylthioxanthyl group, a benzoin group, a (2-hydroxy-3-naphthylvinyl)-di-isopropylsilyl group, a thiochromone S,S dioxide group, a 6-Bromo-4-(1,2-dihydroxyethyl)-7-hydroxycoumarin group, a 4H-benzo[d][1,3]dioxine-2-yl group, a 4,4-bis-phenyl-4H-benzo[d][1,3]dioxine-2-yl group. The thermally labile functionality can be a trimethylalkyl ammonium hydroxide, trimethylalkyl ammonium alkoxide, a Diel-Alder adduct, a beta-carbonyl ester, or a carbamate. The activatable functionality can include an ester, silylester, sulfate ester, phosphate ester, amine, or phosphine. The first and/or the second linker can be a single bond, an oxygen, an unsubstituted or substituted amine, an unsubstituted or substituted methylene, an unsubstituted or substituted alkylene, an unsubstituted or substituted alkenylene, or an unsubstituted or substituted phenylene.

Another embodiment of the invention is directed to a method of preparing the multistage side-chain CP, above, by providing a multiplicity of monomers or conjugated oligomers comprising an ene, diene, arylene, or heteroarylene and leaving groups, where at least one of the monomers comprises a multistage side-chain, and polymerizing the multiplicity of monomers by oxidative polymerization or using a Stille, Suzuki, Kumada, Hiyama, Negishi, or direct arylation method to form the multistage side-chain CP.

Another embodiment of the invention is directed to a method of preparing an insoluble film of a CP by: providing the multistage side-chain CP described above in an organic solution; adding a chemical agent to convert the multistage side-chain CP to an aqueous soluble activated multistage side-chain CP; dissolving the aqueous soluble activated multistage side-chain CP in a solvent including water; depositing the activated multistage side-chain CP solution as a film on a substrate; photolytically cleaving or thermally cleaving the photolytically labile functionality or thermally labile functionality to separate the core CP from a multistage side-chain residue that is soluble and/or volatile; and removing the multistage side-chain residue to leave the core CP as an insoluble CP film on the substrate. The CP film on the substrate can be a portion of an organic electronic device.

### BRIEF DESCRIPTION OF DRAWINGS

FIG. 1 shows a process flow scheme for processing of multistage side-chain cleavable conjugated polymers (CPs) where the CP is synthesized as organic soluble, converted to an aqueous soluble CP through trigger 1, and converted to an insoluble CP through trigger 2, according to an embodiment of the invention.

FIG. 2A shows a structural diagram for a multistage side-chain CP (P(T3-MS)—O), according to an embodiment of the invention, in relation to a chemical structure for an exemplary multistage side-chain CP, according to an embodiment of the invention.

FIG. 2B shows the structure of an exemplary multistage side-chain CP (P(DPP-DTT-MS)), according to an embodiment of the invention.

FIG. 3 shows an annotated structure of P(T3-MS)—O where possible structural modifications to the polythiophene are noted, according to embodiments of the invention.

FIG. 4A shows overlaid UV-vis spectra of P(T3-MS)—O, according to an embodiment of the invention, irradiation, after irradiation, and after washing the irradiated polymer.

FIG. 4B shows overlaid UV-vis spectra of P(T3-MS)—PE, according to an embodiment of the invention, irradiation, after irradiation, and after washing the irradiated polymer.

FIG. 5A shows ¹H NMR spectra for P(T3-MS)—O in solution and the soluble portion after irradiation, according to an embodiment of the invention.

FIG. 5B shows ¹H NMR spectra for P(T3-MS)—PE in solution and the soluble portion after irradiation, according to an embodiment of the invention.

FIG. 6 shows photographs of water drops on the surface of films of P(T3-MS)—O and P(T3-MS)—PE after deposition and after irradiation and washing cleaved side-chain from the film and the measured contact angle of the drops, according to embodiments of the invention.

FIG. 7A shows a grazing-incidence wide-angle X-ray scattering (GIWAXS) plot of a P(T3-MS)—PE thin film as cast, according to an embodiment of the invention.

FIG. 7B shows a GIWAXS plot of a P(T3-MS)—PE thin film after irradiation of the cast film of FIG. 7A, according to an embodiment of the invention.

FIG. 7C shows a GIWAXS plot of a P(T3-MS)—PE thin film after washing with 1:1 H₂O:IPA of the irradiated film of FIG. 7B, according to an embodiment of the invention.

FIG. 8A shows plotted N:S atomic ratios in a P(T3-MS)—PE thin film as deposited, irradiated, and subsequent washing at various depths from the surface in contrast to the expected ratio of 0.33 based on the atomic composition of P(T3-MS)—PE, according to an embodiment of the invention.

FIG. 8B shows plotted K:S atomic ratios in a P(T3-MS)—PE thin film as deposited, irradiated, and subsequent washing at various depths from the surface in contrast to the expected ratio of 0.66 based on the atomic composition of P(T3-MS)—PE, according to an embodiment of the invention.

FIG. 9A shows averages, of three devices, for OFET transfer curves and average hole mobility values of P(T3-MS)—O films in their pristine state and after irradiation and washing, according to an embodiment of the invention.

FIG. 9B shows averages, of nine devices, for OFET transfer curves and average hole mobility values of P(T3-MS)—PE films in their pristine state and after irradiation and washing, according to an embodiment of the invention.

FIG. 10A shows cyclic voltammetry (CV) and differential pulse voltammetry (DPV) data of P(T3-MS)—PE cast onto a glassy carbon button (working) electrode, a platinum flag (counter) electrode, a reference electrode (Ag/Ag⁺, 10 mM AgNO₃ in 0.5 M TBAPF₆-ACN, E_{1/2} for ferrocene: 68 mV), with 0.5M TBAPF6/PC as the supporting electrolyte where scans were taken at 50 mV/s.

FIG. 10B shows cyclic voltammetry (CV) and differential pulse voltammetry (DPV) data of P(T3-MS)—O as cast and after irradiation onto a glassy carbon button (working) electrode, a platinum flag (counter) electrode, a reference electrode (Ag/Ag⁺, 10 mM AgNO₃ in 0.5 M TBAPF₆-ACN, E₁ for ferrocene: 68 mV), with 0.5M TBAPF6/PC as the supporting electrolyte where scans were taken at 50 mV/s.

FIG. 11A shows a spectroelectrochemical series for aqueous processed P(T3-MS)—PE film on ITO/glass in its pristine state with photographs of the film in its neutral (red) and oxidized (colorless) states, where spectra and photos were taken in a three electrode cell setup with ITO serving as the working electrode, a platinum flag as the counter electrode, and a reference electrode (Ag/Ag⁺, 10 mM AgNO₃ in 0.5 M TBAPF₆-ACN, E_{1/2} for ferrocene: 68 mV) with 0.5 M tetrabutylammonium hexafluorophosphate-propylene carbonate as the supporting electrolyte.

FIG. 11B shows a spectroelectrochemical series for aqueous processed P(T3-MS)—PE film on ITO/glass after irradiation and washing with photographs of the film in its neutral (red) and oxidized (colorless) states, where spectra and photos were taken in a three electrode cell setup with ITO serving as the working electrode, a platinum flag as the counter electrode, and a reference electrode (Ag/Ag⁺, 10 mM AgNO₃ in 0.5 M TBAPF₆-ACN, E_{1/2} for ferrocene: 68 mV) with 0.5 M tetrabutylammonium hexafluorophosphate-propylene carbonate as the supporting electrolyte.

FIG. 11C shows a spectroelectrochemical series for aqueous processed P(T3-MS)—O film on ITO/glass in its pristine state with photographs of the film in its neutral (red) and oxidized (colorless) states, where spectra and photos were taken in a three electrode cell setup with ITO serving as the working electrode, a platinum flag as the counter electrode, and a reference electrode (Ag/Ag⁺, 10 mM AgNO₃ in 0.5 M TBAPF₆-ACN, E_{1/2} for ferrocene: 68 mV) with 0.5 M tetrabutylammonium hexafluorophosphate-propylene carbonate as the supporting electrolyte.

FIG. 11D shows a spectroelectrochemical series for aqueous processed P(T3-MS)—O film on ITO/glass after irradiation and washing with photographs of the film in its neutral (red) and oxidized (colorless) states, where spectra and photos were taken in a three electrode cell setup with ITO serving as the working electrode, a platinum flag as the counter electrode, and a reference electrode (Ag/Ag⁺, 10 mM AgNO₃ in 0.5 M TBAPF₆-ACN, E_{1/2} for ferrocene: 68 mV) with 0.5 M tetrabutylammonium hexafluorophosphate-propylene carbonate as the supporting electrolyte.

FIG. 12A shows plots of switching of potentials between −0.5 V and 0.8 V for various time frames for a P(T3-MS)—PE film before and after irradiation using the device used for the spectroelectrochemistry experiments of FIGS. 11A and 11B, and monitored at λₘₐₓ.

FIG. 12B shows plots of switching of potentials between −0.5 V and 0.8 V for various time frames for a P(T3-MS)—O film before and after irradiation using the device used for the spectroelectrochemistry experiments of FIGS. 1C and 11D, and monitored at λₘₐₓ.

FIG. 13A shows a reaction scheme for the preparation of the monomer bearing the multistage side-chain and its polymerization to P(T3-MS)—O, according to an embodiment of the invention.

FIG. 13B shows a reaction scheme for the two-step end-capping of the P(T3-MS)—O, as formed in the scheme of FIG. 13A, according to an embodiment of the invention.

FIG. 14 shows a reaction scheme for the conversion of P(T3-MS)—O to P(T3-MS)—PE, according to an embodiment of the invention.

FIG. 15 shows a composite plot of UV-vis spectra for P(T3-MS)—O and P(T3-MS)—PE in solution and as a thin film, according to embodiments of the invention.

FIG. 16A shows offset 1D line cuts in the qxy direction for P(T3-MS)—PE pristine, irradiated, and irradiated and washed films.

FIG. 16B shows an offset 1D line cuts in the qz direction for P(T3-MS)—PE pristine, irradiated, and irradiated and washed films.

FIG. 17A shows an XPS survey spectrum for P(T3-MS)—PE at the surface of a film.

FIG. 17B shows an XPS survey spectrum for P(T3-MS)—PE, through the thickness of the film.

FIG. 18A shows representative XPS peak decomposition for a spectrum taken at the P(T3-MS)—PE surface in the S2p region.

FIG. 18B shows representative XPS peak decomposition for a spectrum taken at the P(T3-MS)—PE surface in the N1s region.

FIG. 18C shows representative XPS peak decomposition for a spectrum taken at the P(T3-MS)—PE surface in the K2p region.

FIG. 19A shows Ns and K2p XPS spectra for pristine, irradiated, and irradiated and water/IPA washed films of the P(T3-MS)—PE at the film's top surface.

FIG. 19B shows N1s and K2p XPS spectra for pristine, irradiated, and irradiated and water/IPA washed films of the P(T3-MS)—PE at the film's bottom surface.

### DETAILED DISCLOSURE

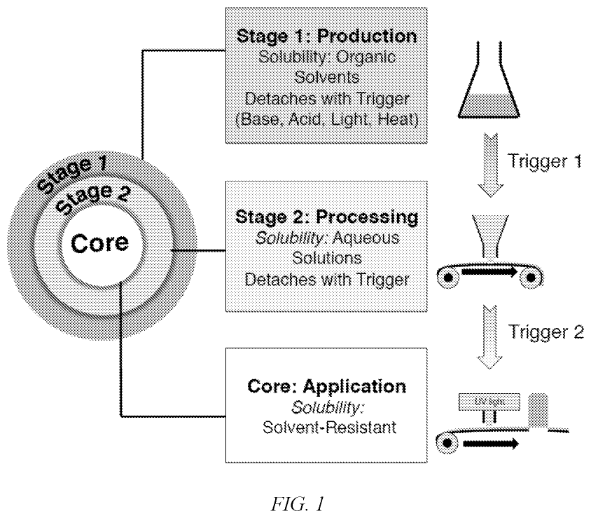

Embodiments of the invention are directed to conjugated polymers (CPs) with functionality for multistage side-chain cleavage, where two orthogonal processes for cleavage of the functionalities enabling aqueous deposition to an insoluble CP for organic electronic materials. The CPs have a multiplicity of repeating units that form a conjugated backbone and comprise side-chains that have multiple responsive functionalities, referred to herein as “multistage side-chains” having CP backbones that allow: in a first stage a traditional polymer synthesis, purification, and characterization in organic solvents; in a second stage conversion to an “aqueous soluble” CP for processing; and in a third stage conversion to an insoluble CP to act as a robust thin film for a device. The general concept of multistage side-chain processing is outlined in FIG. 1. It should not be inferred that subsequent CPs of the multistage process are necessarily of smaller volume or mass. In this manner a CP in aqueous solution can be printed onto a substrate without the use of a surfactant. After printing, the second responsive functionality can be triggered to remove the aqueous solubilizing side-chains to transition to a “core” CP that is insoluble and a multistage side-chain residue that is soluble in an aqueous solvent or volatile at temperatures of 0 to 150° C. and pressure of 1×10⁻⁵ to 1 atmosphere. The core CP is primarily made up of the conjugated backbone without solubilizing groups, providing an insoluble electroactive film ready for application in an electronic device. The core CPs can be the active material in an organic photovoltaic (OPV) device, an organic field effect transistor (OFET), an electrochromic (EC) device, an electrochemical charge storage device, an organic photodetector, a chemical sensor, a bio-sensor, an organic electrochemical transistor, an organic light emitting diode, or an organic light emitting electrochemical cell.

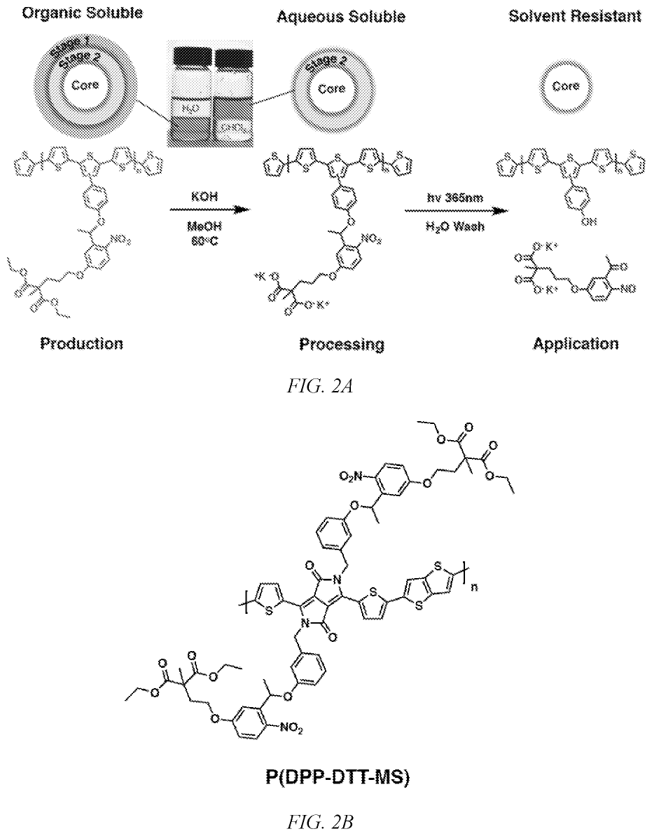

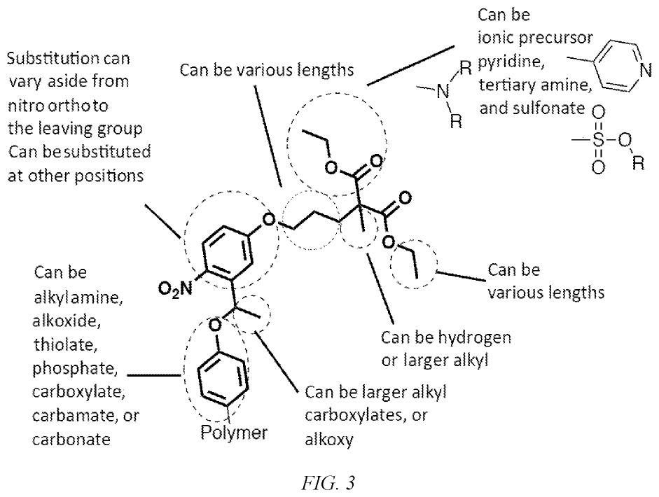

An exemplary CP with multistage side-chains and its chemical conversion to its core CP is shown in FIG. 2. The exemplary CP with multistage side-chains is a regular (A₂B)ₙ type copolymer poly(thiophene-co-thiophene-multistage-side-chain) where there are two thiophene repeating units separating every thiophene-multistage-side-chain repeating unit along the polymer chain. The CPs with multistage side-chains according to embodiments of the invention are not so limited, as the CP can be a homopolymer (A), of the repeating unit comprising the multistage side-chain or a copolymer, which can be, for example, but not limited to: regular (AB)ₙ, (A,B)ₙ where x is 2 to 6, (AₓB_{y}) where x and y are independently 2 to 6; (AₓB_{y}AₓC_{z})ₙ or (AₓB_{y}C_{z}B_{y}Aₓ)ₙ where x, y, and z are independently 1 to 6; or random [(A)ₓ(B)_{y}]ₙ where x and y are independently on average 1 to 10 or [(A)ₓ(B)_{y}(C)_{z}]ₙ where x, y, and z are independently 1 to 10; and where one of any of A, B, or C can be the repeating unit with the multistage side-chain. As can be appreciated by one of ordinary skill in the art, these possibilities can be extended to copolymers with 4, 5 or more different repeating units and where more than one repeating unit may contain a multistage side-chain. The CPs with multistage side-chains, according to embodiments of the invention, can be extended to copolymers that are quasi-regular, where, for example, (A,B) where x is on average 2 to 6 but never less than 2 and not a normal distribution, or is quasi-random, for example, (AₓB_{y})ₙ where x and y are independently 2 to 6 and neither x and/or y can be less than 2 and not a normal distribution. Degrees of polymerization, as characterized in the structures above as: n, 2n, n(x+1), n(x+y), n(x+y+z), n(2x+y+z), or n(2x+2y+z), can be of any value between 10 to 100,000.

In embodiments of the invention, the CPs with multistage-side-chains can comprise repeating units where the conjugated backbone has unsubstituted or substituted repeating units selected from: 3,4-(1,2-phenylene)-dioxytellurophene; 3,4-(1,2-vinylene)-dioxytelurophene; 3,4-diaminotelurophene; 3,4-dicyanotelurophene; 3,4-diethenyloxytelurophene; 3,4-diformyloxytelurophene; 3,4-diphenoxytelurophene; benzothiadiazoles; telurophene-3,4-dicarboxylic acid; [1,2,5]oxadiazolo [3,4-c]pyridine; [1,2,5]thiadiazolo[3,4-c]pyridine; [1,2,5]thiadiazolo[3,4-g]quinoxaline; 1,3,4-oxadiazole; 1,3,4-thiadiazole; 1,3,4-triazole; 2,2′-bithiazole; 3,4-(1,2-phenylene)dioxyfuran; 3,4-(1,2-phenylene)dioxypyrrole; 3,4-(1,2-phenylene)dioxyselenophene; 3,4-(1,2-phenylene)dioxythiophene; 3,4-(1,2-vinylene)-dioxyfuran; 3,4-(1,2-vinylene)dioxypyrrole; 3,4-(1,2-vinylene)dioxyselenophene; 3,4-(1,2-vinylene)dioxythiophene; 3,4-alkylenedioxyfuran; 3,4-alkylenedioxypyrrole; 3,4-alkylenedioxyselenophene; 3,4-alkylenedioxytelurophene; 3,4-alkylenedioxythiophene; 3,4-dialkyfuran; 3,4-dialkypyrrole; 3,4-dialkyselenophene; 3,4-dialkythiophene; 3,4-diaminofuran; 3,4-diaminopyrrole; 3,4-diaminoselenophene; 3,4-diaminothiophene; 3,4-dicyanofuran; 3,4-dicyanopyrrole; 3,4-dicyanoselenophene; 3,4-dicyanothiophene; 3,4-diethenyloxyfuran; 3,4-diethenyloxypyrrole; 3,4-diethenyloxyselenophene; 3,4-diethenyloxythiophene; 3,4-diformyloxyfuran; 3,4-diformyloxypyrrole; 3,4-diformyloxyselenophene; 3,4-diformyloxythiophene; 3,4-dihalofuran; 3,4-dihalopyrrole; 3,4-dihaloselenophene; 3,4-dihalotelurophene; 3,4-dihalotelurophene; 3,4-dihalothiophene; 3,4-dihalothiophene; 3,4-dihydroxyfuran; 3,4-dihydroxypyrrole; 3,4-dihydroxyselenophene; 3,4-dihydroxytelurophene; 3,4-dihydroxythiophene; 3,4-dioxyfuran; 3,4-dioxypyrrole; 3,4-dioxyselenophene; 3,4-dioxytelurophene; 3,4-dioxythiophene; 3,4-diphenoxyfuran; 3,4-diphenoxypyrrole; 3,4-diphenoxyselenophene; 3,4-diphenoxythiophene; 3,5-dialkoxy-dithieno[3,2-b:2′,3′-d]thiophene; 3,6-dialkoxythieno[3,2-b]thiophene; 4,4′-bis(alkyl)-[6,6′-bithieno[3,2-b]pyrrolylidene]-5,5′(4H,4′H)-dione; 4-dicyanomethylenecyclopentadithiolene; benzo[1,2-b:6,5-b′]dithiophene-4,5-dione; anthracene; benzo[1,2-c;4,5-c′]bis[1,2,5]-thiadiazole; benzo[c][1,2,5]oxadiazole; benzo[c]thiophene; benzo[d][1,2,3]triazole; benzobisthiadiazole; benzothiadiazole; carbazole; cyanovinylene; cyclopentadithiophene-4-one; dicyanovinylene; dithieno[3,2-b:2′,3′-d]thiophene; ethene; fluorene; furan; furan-3,4-dicarboxylic acid; indigo; isoindigo; naphthalene; napthalenediimide; perylenediimide; phenanthrene; phenanthrene-9,10-dione; phenylene; pyrazine; pyrazinoquinoxaline; pyrene; pyrido[3,4-b]pyrazine; pyrrole; pyrrolo[3,4-c]pyrrole-1,4-dione; quinoline; quinoxaline; selenophene; selenophene-3,4-dicarboxylic acid; telurophene; thiadiazoloquinoxaline; thiadiazolothienopyrazine; thiazolo[5,4-d]thiazole; thiazolo[5,4-d]thiazole; thieno[3,2-b]thiophene; thieno[3,4-b]pyrazine; thieno[3,4-b]pyrazine; thienopyrazine; thienothiadiazole; thienothiadiazole; thiophene; thiophene-3,4-dicarboxylic acid; any other aromatic or heteroaromatic; any fused aromatic and/or heteroaromatic units; or any fused or plurally fused combination thereof. The fused or plural fused repeating units can be of the same or different structure.

The repeating units and the monomers, from which the repeating units are formed, other than the repeating units with the multistage side-chain, can be substituted in the appropriate positions. Substituents are selected by one of ordinary skill in the art such that the substituent is passive under the chosen method of synthesis, activation, deposition, and cleavage to the final core CP and to provide the desired properties of the core CP. Substituents can be selected from: independently H, C₁-C₃₀ alkyl, C₂-C₃₀ alkenyl, C₂-C₃₀ alkynyl, C₆-C₁₄ aryl, C₇-C₃₀ arylalkyl, C₈-C₃₀ arylalkenyl, C₈-C₃₀ arylalkynyl, hydroxy, C₁-C₃₀ alkoxy, C₆-C₁₄ aryloxy, C₇-C₃₀ arylalkyloxy, C₂-C₃₀ alkenyloxy, C₂-C₃₀ alkynyloxy, C₈-C₃₀ arylalkenyloxy, C₈-C₃₀ arylalkynyloxy, CO₂H, C₂-C₃₀ alkylester, C₇-C₁₅ arylester, C₈-C₃₀ alkylarylester, C₃-C₃₀ alkenylester, C₃-C₃₀ alkynylester, NH₂, C₁-C₃₀ alkylamino, C₆-C₁₄ arylamino, C₇-C₃₀ (arylalkyl)amino, C₂-C₃₀ alkenylamino, C₂-C₃₀ alkynylamino, C₈-C₃₀ (arylalkenyl)amino, C₈-C₃₀ (arylalkynyl)amino, C₂-C₃₀ dialkylamino, C₁₂-C₂₈ diarylamino, C₄-C₃₀ dialkenylamino, C₄-C₃₀ dialkynylamino, C₇-C₃₀ aryl(alkyl)amino, C₇-C₃₀ di(arylalkyl)amino, C₈-C₃₀ alkyl(arylalkyl)amino, C₁₅-C₃₀ aryl(arylalkyl)amino, C₈-C₃₀ alkenyl(aryl)amino, C₈-C₃₀ alkynyl(aryl)amino, C(O)NH₂ (amido), C₂-C₃₀ alkylamido, C₇-C₁₄ arylamido, C₈-C₃₀ (arylalkyl)amido, C₂-C₃₀ dialkylamido, C₁₂-C₂₈ diarylamido, C₈-C₃₀ aryl(alkyl)amido, C₁₅-C₃₀ di(arylalkyl)amido, C₉-C₃₀ alkyl(arylalkyl)amido, C₁₆-C₃₀ aryl(arylalkyl)amido, thiol, C₁-C₃₀ hydroxyalkyl, C₆-C₁₄ hydroxyaryl, C₇-C₃₀ hydroxyarylalkyl, C₃-C₃₀ hydroxyalkenyl, C₃-C₃₀ hydroxyalkynyl, C₈-C₃₀ hydroxyarylalkenyl, C₈-C₃₀ hydroxyarylalkynyl, C₃-C₃₀ polyether, C₃-C₃₀ polyetherester, C₃-C₃₀ polyester, C₃-C₃₀ polyamino, C₃-C₃₀ polyaminoamido, C₃-C₃₀ polyaminoether, C₃-C₃₀ polyaminoester, C₃-C₃₀ polyamidoester, or C₃-C₃₀alkylsulfonic acid. Alkyl groups can be straight, branched, multiply branched, cyclic, or polycyclic where cyclic and polycyclics can be unsubstituted, substituted, or polysubstituted, alkenyl can be a monoene, conjugated or non-conjugated polyene, straight, branched, multiply branched, cyclic, or polycyclic, terminal or internal, substituted at any carbon, E or Z isomers or mixture thereof, alkynes can be mono-yne, conjugated or non-conjugated poly-yne, terminal or internal, substituted at any carbon, aryl groups can be cyclic, fused or unfused polycyclic of any geometry, asymmetric functional groups, such as ester and amido, can have either orientation with respect to the alkylenedioxythiophene rings, poly can be 2 or more. Heteroatoms can be at any position of those substituents, for example, oxygens of ethers or esters or nitrogens of amines or amides can be in the alpha, beta, gamma or any other position relative to the point of attachment the portion of the repeating unit that defines the conjugated backbone. Heteroatom containing substituents can have a plurality of heteroatoms, for example, ether can be a monoether, a diether or a polyether, amine can be a monoamine, a diamine or a polyamine, ester can be a monoester, a diester, or a polyester, and amide can be a monoamide, a diamide or a polyamide. Ethers and esters groups can be thioethers, thioesters and hydroxy groups can be thiol (mercapto) groups, where sulfur is substituted for oxygen.

Polymerization to the CPs with multistage-side-chains is carried out in organic solvent, allowing for the use of traditional polymerization methods, such as, but not limited to, oxidative, Stille, Suzuki, Kumada, Hiyama, Negishi, and direct arylation methods, where the appropriate solvent and catalyst and leaving groups are those taught in the art, and would be appreciated by one of ordinary skill in the art. This allows the polymer's purification and characterization under mild conditions, such as low to moderate temperatures and/or light intensities to provide the desired polymer for chemical activation of a solubilizing portion to form an aqueous solution of an ionic CP for deposition on a substrate.

The repeating unit with the multistage side-chain can have a backbone portion that is of one or more of any of the above repeating unit structures and has a side chain comprising: a photo- or thermal-cleavable portion; a linker between the backbone portion and the cleavable portion; a chemically activatable solubilizing portion; and a linker between the solubilizing portion and the cleavable portion. FIG. 2 shows a thiophene backbone portion that is attached through a linking benzoxy unit to an o-nitrobenzyl group comprising photo-cleavable portion that is linked to a di-ester that can be chemically activated by base catalyzed hydrolysis to a dicarboxylic acid salt. In this exemplary embodiment, a polythiophene bearing multistage side-chains, P(T3-MS)—O is formed. This polythiophene can transition from an organic soluble CP to an aqueous soluble polyelectrolyte CP, P(T3-MS)—PE, by saponification of the ester groups to carboxylates. The o-nitrobenzyl functionality can subsequently be cleaved to liberate a portion of the side-chain through UV excitation of the nitro group and rearrangement to cleave the aqueous solubilized and cleavable portion from the linker to the repeating unit in the backbone of the CP, yielding an insoluble polymer P(T3-MS)—I. Even with the cleavable portion coupled with the solubilizing portion of the exemplary embodiment of FIG. 2A, the structure can vary significantly, as illustrated in FIG. 2B for P(DPP-DTT-MS), where the backbone has a different structure and the repeating unit with the multistage side-chain is different. FIG. 3 illustrates the nature of possible variations of the linkers and cleavable and solubilizing portions relative to the exemplary embodiment are given, but as can be appreciated by one of ordinary skill in the art FIG. 3 is not exhaustive in the number of possibilities, according to embodiments of the invention.

In embodiments of the invention, the linker to the aromatic or heteroaromatic backbone portion of the repeating unit can be substituted in a position that does not adversely compromise conjugation within the backbone, where the linker comprises at least one covalent bond through a series of covalent bonds to an atom that is of the cleavable portion of the multistage side-chain. The cleavable portion is connected through a plurality of covalent bonds to a portion, which can be chemically activated to a functionality that provides solubility in water. The cleavable portion can be photo-labile and comprise an o-nitrobenzyl group, a 9-phenylthioxanthyl group, a benzoin group, a (2-hydroxy-3-naphthylvinyl)-di-isopropylsilyl group, thiochromone S,S dioxide group, 6-Bromo-4-(1,2-dihydroxyethyl)-7-hydroxycoumarin group, 4H-benzo[d][1,3]dioxine-2-yl group, 4,4-bis-phenyl-4H-benzo[d][1,3]dioxine-2-yl group or any other group where the linker to the backbone portion leaves an alcohol, phenol, thiol, aldehyde, ketone, or amine functionality resident in the core CP. One of ordinary skill in the art can readily associate the appropriate functionality of the linker with the photo-labile group or appropriate substituents for the photo-labile group to enhance yields of its formation and/or cleavage. The light source and wavelength range required for irradiation is defined by the structure of the photo-labile group and its substituents, where the irradiation can be in the visible or ultraviolet region of the spectrum. The cleavable portion can be thermal-labile and comprise, for example: a trimethylalkyl ammonium hydroxide or trimethylalkoxide that also acts as the aqueous solubilizing portion when transformed from the organic soluble polymer by methylation of a dimethylalkyl amine or dimetylalkoxy amine, which can undergo Hofmann elimination to leave an alkene functionality from the linker resident in the core CP; a substituted cyclopentadiene or furan Diels-Alder adduct where an ene comprising core unit is liberated at moderate temperatures; a carbamate, for example a substituted Boc protecting group in the presence of some water residual from the aqueous deposition of the polymer, allows liberation of an amine comprising core unit; a beta-carbonyl ester, where thermal decarboxylation can induce cleavage; or any other thermally labile unit that can be or can be attached to the aqueous soluble portion. These and other photo- and thermal cleavage reactions can be readily envisioned by one of ordinary skill in the art. The heat can be provided by an oven, a hotplate, and infrared heater, a heated gas or liquid, or any other manner. The temperature for cleavage must be less than the temperature where decomposition to the CP or necessary substituents can occur, generally, but not necessarily, below 200° C., below 150° C., or below 120° C. Typically the temperature will exceed any temperature required during the fabrication of the repeating unit with the multistage side-chain or any anticipated storage temperature. Higher temperatures can be tolerated by many conjugated polymers, and temperatures as high as 250° C. can be envisioned.

The solubilizing portion can include an activatable ester, silylester, sulfate ester, phosphate ester, amine, phosphine, or other functionality that can be converted to an ion upon the action of an acid, a base, alkylating agent, or fluoride ion, when a silylester is used as the activatable functionality. Acids can include any acid that will not oxidize or otherwise compromise the core portion of the CP, or change the cleavable portion to render it inactive upon applying the thermal or light trigger. The sulfonate salts, carboxylate salts, thiocarboxylate salts, or dithiocarboxylate formed upon conversion to stage 2 can be those of alkali or alkali earth metals, ammonium salts, or phosphonium salts. The amines or phosphines can be converted into ammonium salts or phosphonium salts by protonation or alkylation, where the alkylating agent can further include functionality with a high water affinity, such as, but not limited to hydroxyl, polyether, amide, or thiol functionality, where the counterion upon conversion to the salt can be a halide, sulfate, acetate, trifluoroacetate, methylsulfinate, trifluromethylsulfnate, phosphate, or any other anion. Once the aqueous soluble activated multistage side-chain CP is formed, it can be deposited on a substrate by slot-die coating, gravure coating, knife-over-edge coating, off-set coating, spray coating, ink jet printing, pad printing, or screen printing.

In an exemplary embodiment, P(T3-MS)—O was synthesized via Stille polymerization in toluene from a distannyl bithiophene with a dibromothiophene bearing the multistage side-chain. A portion of the polymer was stirred overnight in a solution of potassium hydroxide and methanol, yielding an aqueous soluble polyelectrolyte P(T3-MS)—PE. The transition from P(T3-MS)—O in Stage 1 to P(T3-MS)—PE in Stage 2 was affirmed by its solubility in aqueous soluble, the loss of ethyl groups as observed by ¹HNMR, and a change in water contact angle on thin films from 70° for P(T3-MS)—O to 50° for P(T3-MS)—PE.

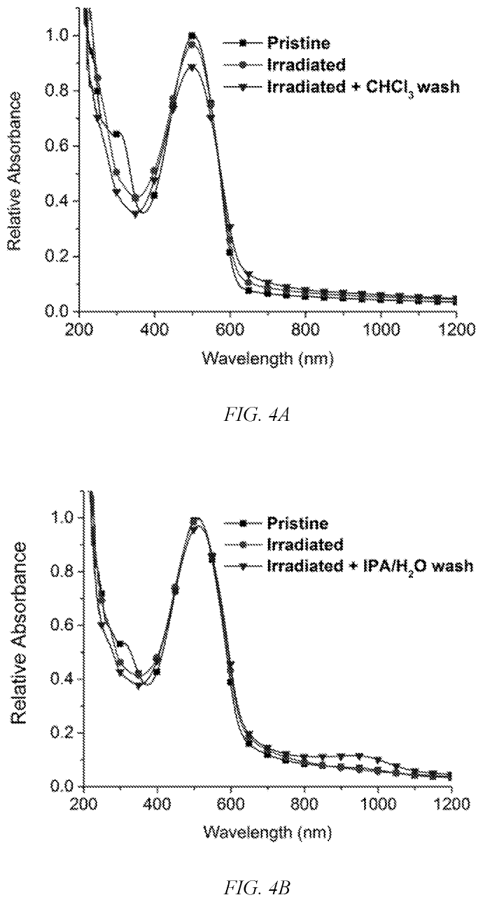

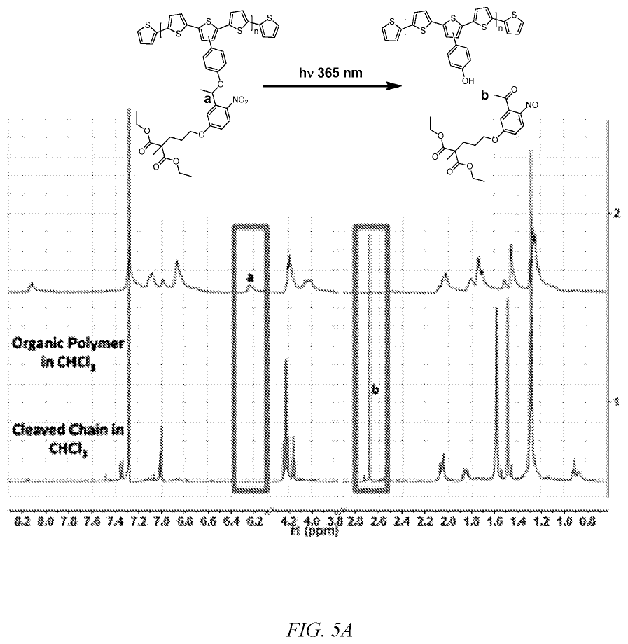

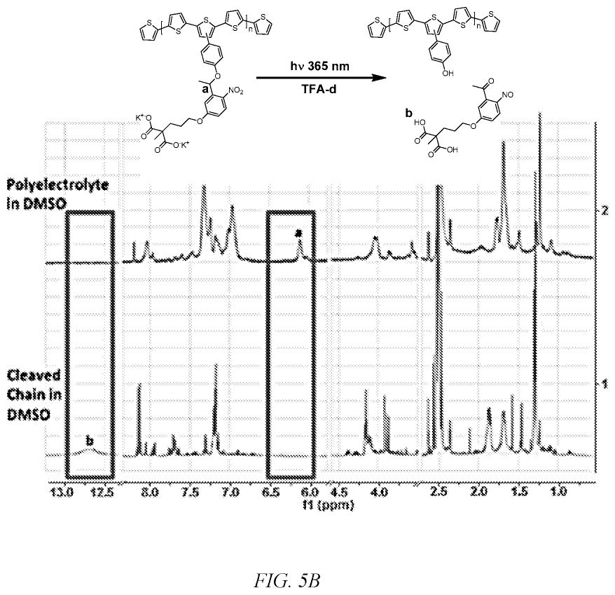

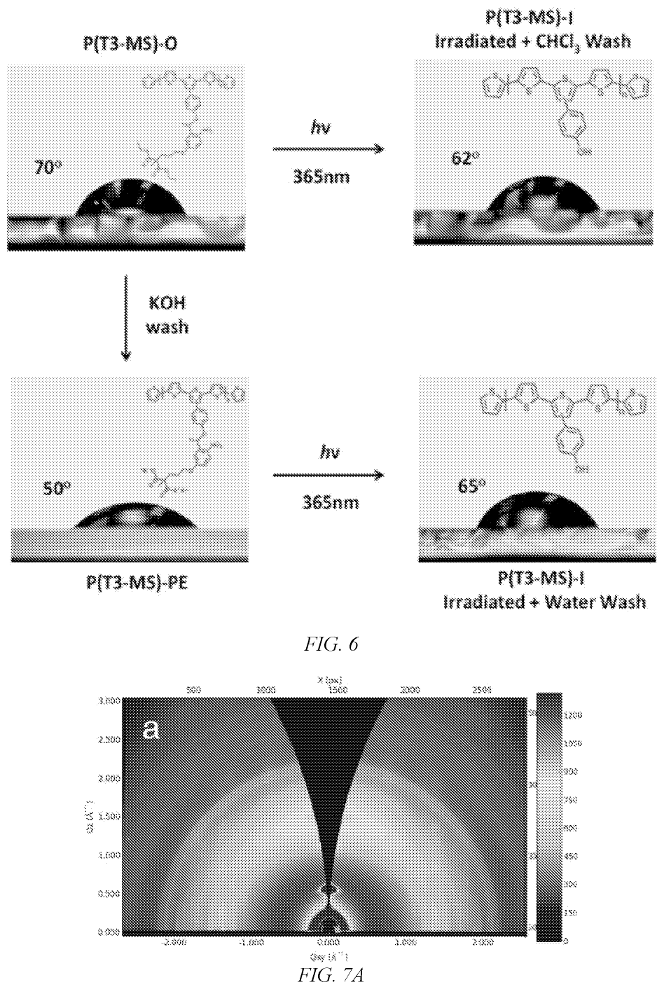

Remaining with the exemplary embodiment, the effectiveness of the UV cleavage using the o-nitrobenzyl functionality was apparent from films of P(T3-MS)—O and P(T3-MS)—PE blade coated onto glass slides from chloroform and 1:1 water:isopropyl alcohol (H₂O:IPA), respectively. Both were irradiated at 365 nm and 5 mW/cm² 150 minutes. As can be appreciated by one of ordinary skill in the art, greater light intensities or energies allow for more rapid photolytic cleavage. For example, using a UV light source centered at 302 nm (UVB) allows cleavage of the side chains within 10 minutes of irradiation and a UV lamp intensity of 80 mW/cm² allows cleavage within 10 seconds of irradiation. IPA was used as a co-solvent to reduce surface tension of the deposition solution of P(T3-MS)—PE, and to enhance wetting and film formation during blade coating. UV-vis spectra before and after irradiation are shown in FIGS. 4A and 4B for P(T3-MS)—O films and P(T3-MS)—PE films, respectively. The main feature of note in the UV-vis spectra is a minimal change in the conjugated backbone π to π* transition and the loss of a peak around 312 nm for both CPs, which can be attributed to the transition from an o-nitrobenzyl group to the cleaved nitroso group. In both cases, irradiation leads to a loss of this peak, while subsequent rinsing in the casting solvent leads to a negligible loss in peak absorption, indicating that the polymer has become solvent resistant after UV irradiation. As shown in FIGS. 5A and 5B, samples from irradiated CP solutions of P(T3-MS)—O and P(T3-MS)—PE reveal the loss of the ¹H NMR peak for the benzyl proton when converted into a ketone during the photo-cleaving process. Contact angle measurements from films deposited from CP solutions of P(T3-MS)—O and P(T3-MS)—PE, are shown in FIG. 6, where the contact angles of 70° for P(T3-MS)—O, 50° for P(T3-MS)—PE, and 62° and 65°, respectively, for the irradiated and washed films, suggest similar P(T3-MA)-I films upon irradiation.

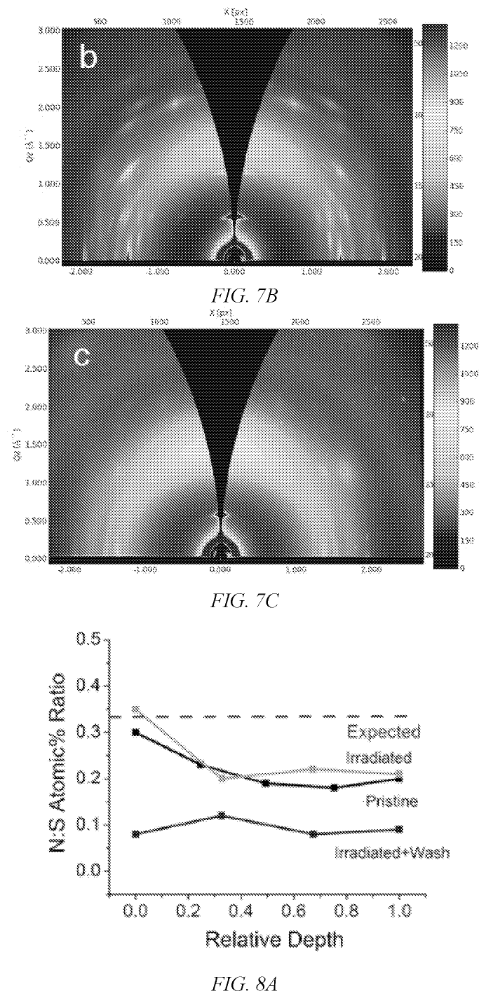

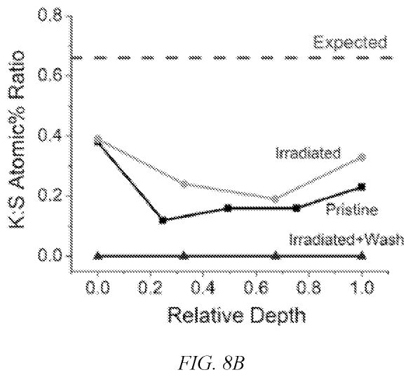

Because side chains of P(T3-MS)—PE contain nitrogen (N) and potassium (K), which are not present in fully converted P(T3-MA)-I, XPS surface and depth profiling experiments on thin films of the deposited CP can quantify the amount of remaining side chain within the film throughout the multistage process. Grazing incidence wide-angle X-ray scattering (GIWAXS) probes structural variations of the polymer throughout the multistage process. As summarized in FIG. 4, integrated peaks for N 1s and K 2p were normalized to the S 2p peak area, which is unique to the polymer backbone, and viewed in reference to the expected repeat unit atomic ratios. For the N is peak, pristine and irradiated films show ratios close to the expected N:S ratio of 0.33. The K²p peaks show similar results, though the K:S ratio was less than the expected value of 0.66, which implies incomplete saponification of the side chains, premature side chain cleavage, and/or a exchange of the K⁺ counterion during deposition. GIWAXS scattering plots, shown in FIGS. 7A-7C, indicate that irradiation leads to a large change (7A→7B); notably formation of discrete crystallite scattering peaks. These peaks, which can be seen as small spots of intensity in FIG. 7B, are commonly indicative of discrete molecular crystallites. The GIWAXS data suggests side chain cleavage upon irradiation, where the cleaved salt forms discrete crystalline domains in the film, which agrees with the minimal changes in atomic makeup seen in the XPS data, as shown in FIGS. 8A and 8B.

Once washed, the N:S ratio drops to 0.1, corresponding to a large loss in nitrogen. Irradiation cleaves the polymer side-chains, but about a third of which are either not cleaved or not washed from the film. The K 2p peaks show complete removal of K after the aqueous wash. These K⁺ counterions can diffuse from the film in conjunction by ion exchange or weak acid protonation of the carboxylates to carboxylic acids. Complete loss of potassium ions, but not side chains may occur by self-doping of the polythiophene backbone by the anionic carboxylates on the side chains. Self-doping is consistent with the peak observed in the spectrum around 1,000 nm for the irradiated and washed P(T3-MS)—PE UV-vis sample in FIG. 4B, which is typical of polaronic charge carriers in conjugated polymers. GIWAXS results of the film after the aqueous wash process (FIG. 7B→7C) show a disappearance of most of the small crystallite peaks, consistent with the significant removal of side-chain mass seen in the XPS atomic ratios. The overall (100) and (010) diffraction pattern for the polymer remains unchanged, with strong edge-on lamellar packing seen along the Qz axis throughout the process. The XPS etching data reveals a similar progression to that observed at the surface, suggesting that these transformations take place throughout the film. Films etched using an argon ion gun with spectra taken at regular intervals through the film display elemental ratios from the surface (relative depth=0) to the interface with the glass substrate (relative depth=1) show some variance as is apparent in FIGS. 8A and 8B. The lower ratios seen in the etched data for pristine and irradiated samples are likely due to partial decomposition and evaporation of the polymer during the plasma etching process, which is consistent with conjugated polymer films. Etching data displays higher carbon content with etching, which is consistent with partial decomposition and evaporation.

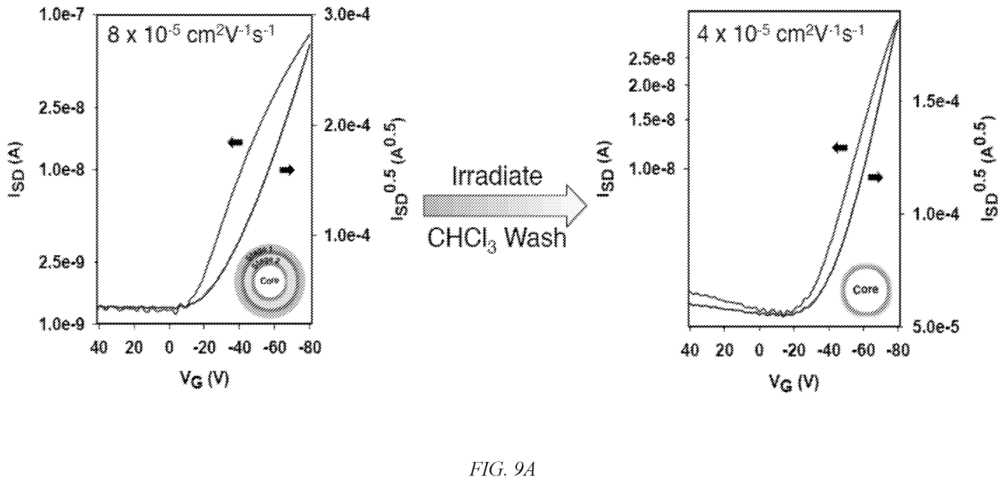

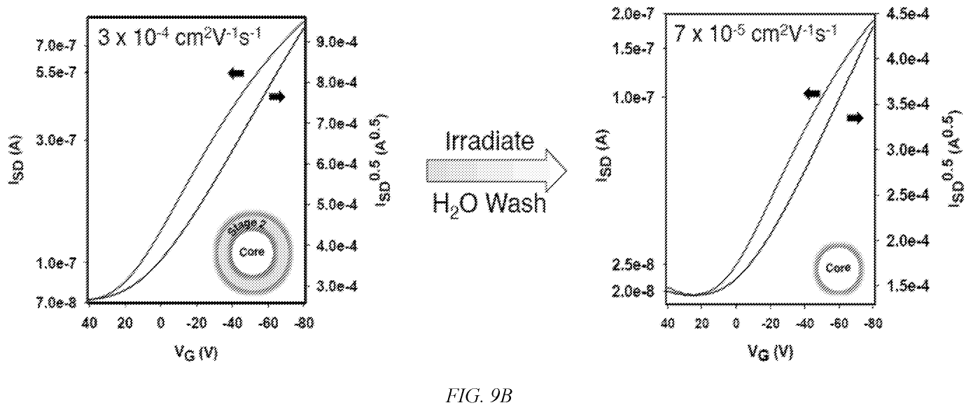

P(T3-MS)—O and P(T3-MS)—PE were tested with regard to solid state OFET mobility and electrochromism in solution, displaying their applicability for device applications. Charge carrier properties were investigated in p-type OFET devices with a bottom-gate/bottom-contact architecture. OFET transfer curves, as shown in FIGS. 9A and 9B display values averaged across 3 P(T3-MS)—O devices and 9 P(T3-MS)—PE devices. Pristine P(T3-MS)—O films cast from chloroform exhibit an average mobility of 8.1×10⁻⁵ cm²V⁻¹s⁻¹, which are of the same order of magnitude as mobility observed for polythiophene deposited from organic solvents with photocleavable side chains (2.6×10⁻⁵ cm²V⁻¹s⁻¹) and that of region-random P3HT (10⁻⁴-10⁻⁵ cm²V⁻¹s⁻¹). After irradiation and washing, mobility of 3.7×10⁻⁵ cm²V⁻¹s⁻¹ is observed. Pristine P(T3-MS)—PE films cast from 1:1 H2O:1PA displayed an average mobility of 2.5×10⁻⁴ cm²V⁻¹s⁻¹. This result was unexpected, as typical conjugated polyelectrolytes do not function well in OFET devices due to the presence of mobile counterions and high OFF currents caused by intrinsic conductivity. The only prior art example of a polyelectrolyte OFET material is an n-type polymer making P(T3-MS)—PE novel as a polyelectrolyte p-type OFET. After irradiation and washing of this CP, the mobility drops to 6.8×10⁻⁵ cm²V⁻¹s⁻¹. For P(T3-MS)—O and P(T3-MS)—PE, an intermediate stage was tested after irradiation but before washing, but neither showed an electrical response. OFET mobility may be disrupted by the presence of mobile side-chains that have not yet been removed from the film.

Higher mobility values than those observed with these region-random CPs are possible with regio-regular CPs, where highly planar backbones are similar to high mobility polymers. The aqueous processed multistage side-chain CPs OFETs in this study show high OFF currents, leading to ON/OFF ratios on the order of 10¹.

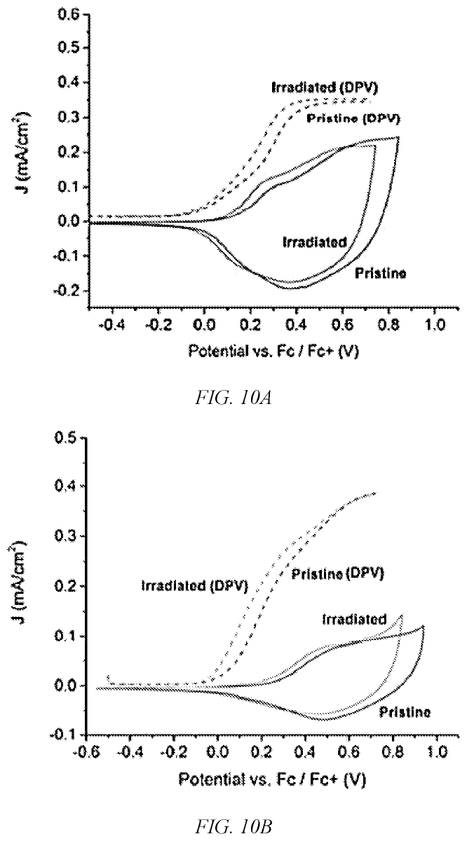

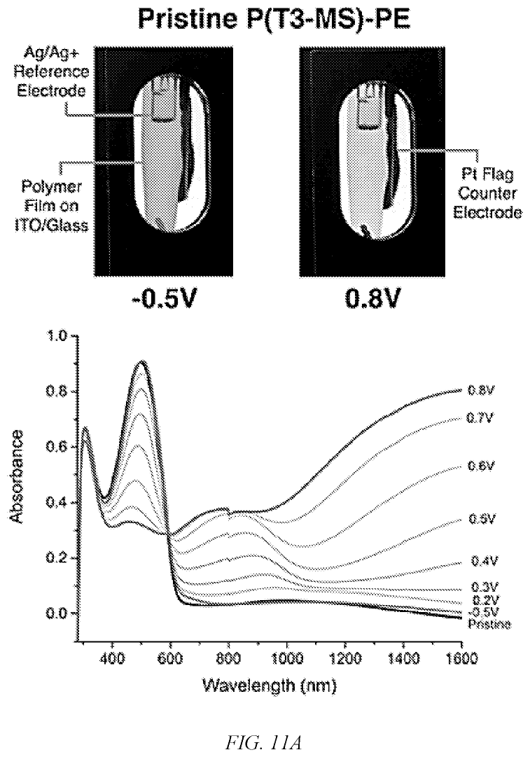

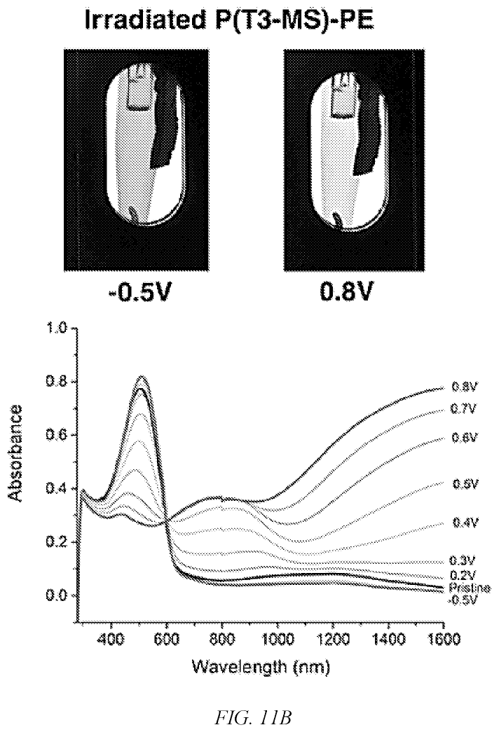

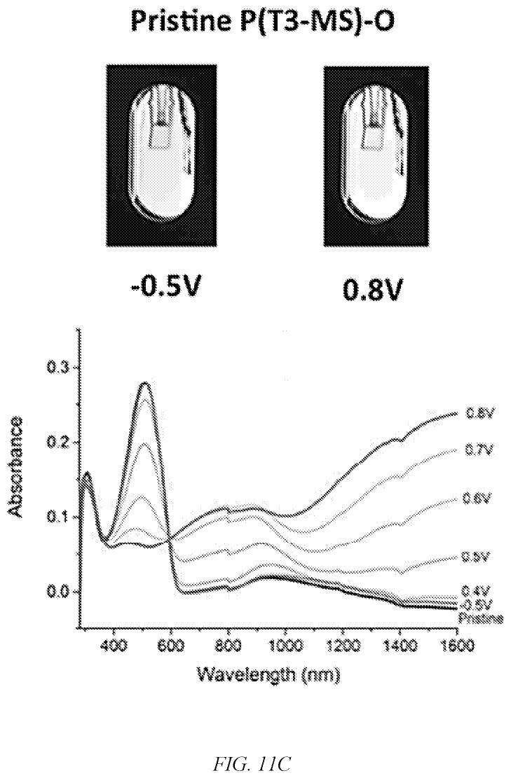

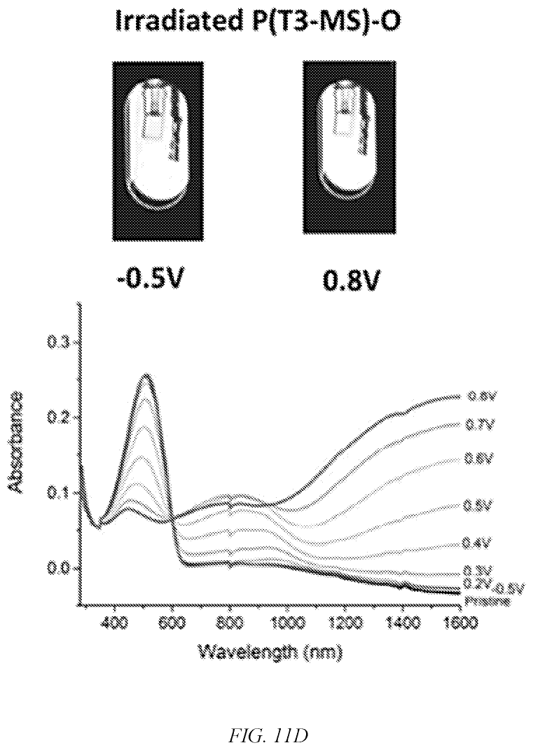

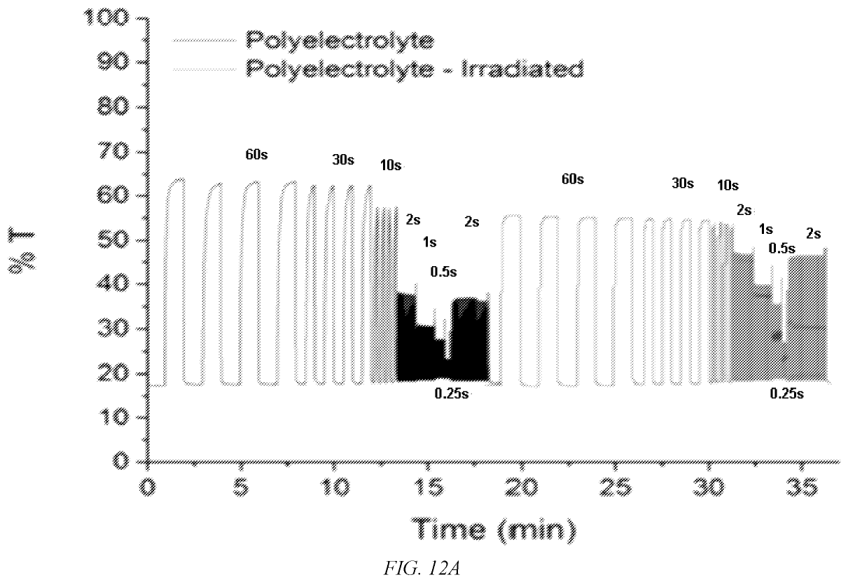

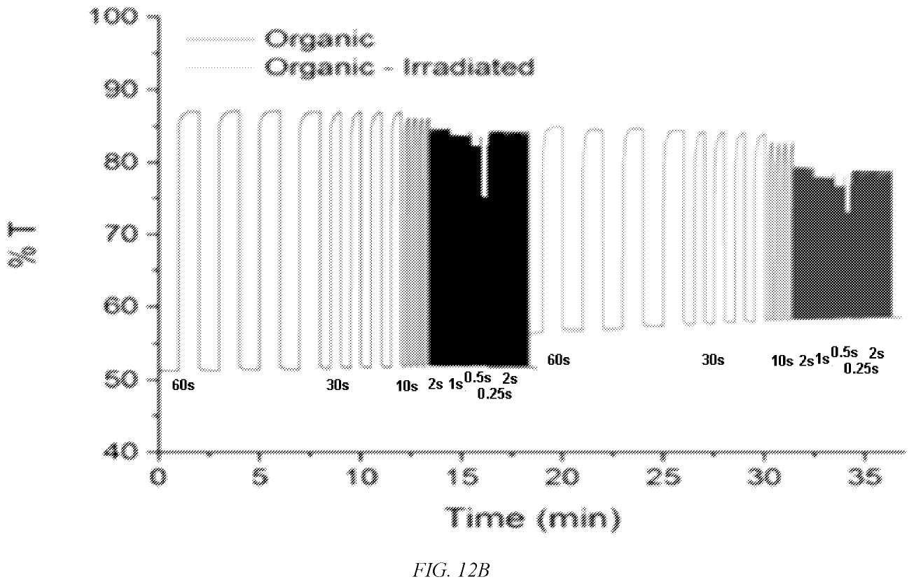

Redox response and red to colorless electrochromism are observed in films of P(T3-MS)—O and P(T3-MS)—PE on ITO/glass before and after irradiation and washing. Broad, reversible oxidation peaks for both CPs show negligible changes in cyclic voltammetry (CV) traces after irradiation, with the onset of oxidation remaining around −0.1 V relative to the ferrocene/ferrocenium redox couple throughout the multistage process. CV and differential pulse voltammetry (DPV) data, are shown in FIGS. 10A and 10B for P(T3-MS)—PE and P(T3-MS)—O, respectively. Oxidation of the CPs is accompanied by a color change from red in the neutral state to colorless in the oxidized state. FIGS. 1A and 11B show spectroelectrochemical series of a P(T3-MS)—PE films on ITO/glass along with photographs of the resulting color (intensity) change in a pristine state and after irradiation and washing, respectively. The electrochromic film has 47% contrast for the pristine polymer and 40% contrast after irradiation, comparable to the 50% contrast achievable in P3HT films. Irradiated films show faster switching speeds, reaching 95% contrast in 6 s, while the pristine films take 14 s. Switching at different rates are shown in FIGS. 12A and 12B for P(T3-MS)—PE and P(T3-MS)—O, respectively. This may be due to superior ion intercalation throughout the film and faster electronic response due to reduced side-chain mass.

### Methods and Materials

Materials

The compounds 4-(2,5-dibromothiophen-3-yl)phenol (M1) and 5,5′-bis(trimethylstannyl)-2,2′-bithiophene were synthesized according to literature procedures. Diethylmethylmalonate (99%, Alfa Aesar), K₂CO₃ (anhydrous, Oakwood Products), sodium hydride (95%, Sigma), 1,3-propanediol di-p-tosylate (98%, Sigma), titanium (IV) chloride (99%, Alfa Aesar), 5-hydroxy-2-nitrobenzaldehyde (95%, Matrix), N-bromosuccinimide (99%, Alfa Aesar), methylmagnesium bromide (3M in diethyl ether, Sigma), triphenylphosphine (99%, Alfa Aesar), Pd₂(dba)₃*CHCl₃ adduct (Sigma), diethyldithiocarbamic acid diethylammonium salt (97%, TCI America), P(o-tolyl)3 (96%, Sigma), 2-bromothiophene (98%, Sigma) and 2-(tributylstannyl)thiophene (97%, Alfa Aesar) were all used as received. N,Ndimethylformamide (anhydrous, Alfa Aesar) and chloroform (BDH) were used as received. Propylene carbonate (Acros Organics), diethyl ether (BDH), tertahydrofuran (BDH), and toluene (BDH) were purified and dried using a solvent purification system. Tetrabutylammonium hexafluorophosphate (TBAPF6, Alfa Aesar, 98%) was recrystallized from ethanol and dried under high vacuum prior to use.

¹H and ¹³C NMR spectra were taken on a 500 MHz Bruker NMR for 32 and 1024 scans, respectively. Chloroform peaks were reference to 7.26 ppm for ¹H spectra and 77.16 ppm for ¹³C spectra.

### Synthesis of P(T3-MS)—O

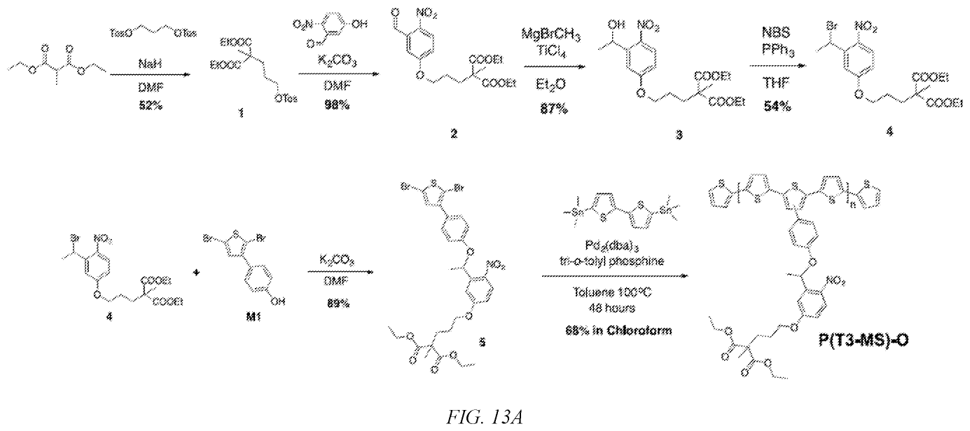

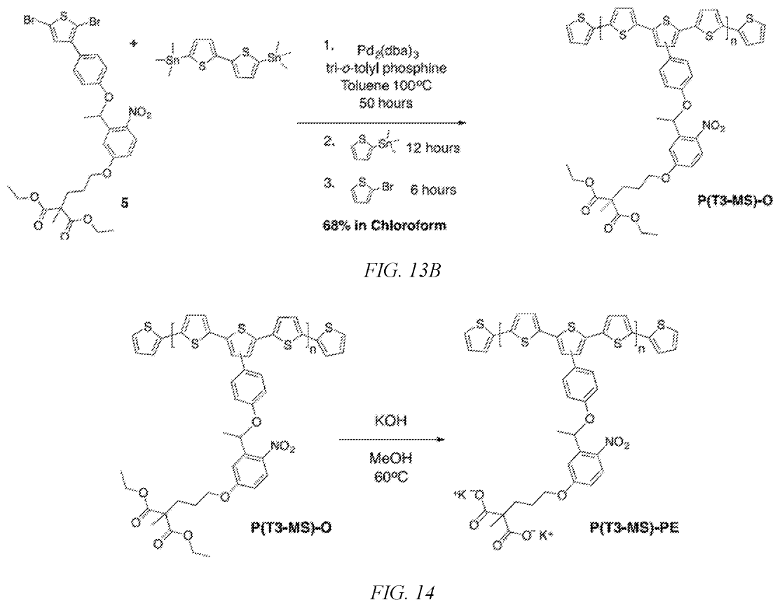

FIG. 13 shows a reaction scheme for the synthesis of P(T3-MS)—O and FIG. 13B shows the exhaustive end-capping of P(T3-MS)—O to assure thiophene ends.

### Diethyl 3-methyl-3-(3-(tosyloxy)propoxy)pentanedioate (1)

Under an argon atmosphere, 993 mg (86.16 mmol) NaH was added to an oven-dried 3-neck round-bottom flask equipped with a condenser and sealed. To the flask was added 200 mL of anhydrous, degassed DMF and 6 g (34.46 mmol) of diethyl methylmalonate was slowly added to the solution. The solution was stirred at room temperature for 30 minutes, and 33 g (86.16 mmol) of propane-1,3-ditosylate was added as a solid to the solution as a solid. The solution was stirred at 50° C. overnight and the reaction was quenched with 25 mL of 1M HCl and 100 mL H₂O. The solution was extracted with EtOAc and the organic layers were washed with H₂O and brine, dried with MgSO₄, filtered, and concentrated by rotary evaporator. The compound was purified by column chromatography using 1:9 EtOAc/hexanes to afford 6.92 g (52%) of 1 as a colorless oil. ¹H NMR (500 MHz, CDCl₃): δ: 7.77 (d, J=8.0 Hz, 2H), 7.34 (d, J=8.0 Hz, 2H), 4.15 (q, J=7.1 Hz, 4H), 4.01 (t, J=6.3 Hz, 2H), 2.44 (s, 3H), 1.84 (m, 2H), 1.62 (m, 2H), 1.35 (s, 3H), 1.22 (t, J=7.1 Hz, 6H). ¹³C NMR (500 MHz, CDCl₃): 171.98, 144.91, 133.12, 129.97, 128.02, 70.41, 61.46, 53.20, 31.74, 24.34, 21.75, 20.04, 14.13. HRMS (ESI MS) m/z: theor: 409.1291 found: 409.1288 (+Na ion found)

### Diethyl 2-(3-(3-formyl-4-nitrophenoxy)propyl)-2-methylmalonate (2)

To an oven-dried 2-neck round-bottom flask, 1.56 g (9.32 mmol) of 5-hydroxy-2-nitrobenzaldehyde and 3.51 g (25.40 mmol) of potassium bicarbonate were added, sealed, and evacuated and refilled with argon 3 times. A 3.29 g (8.47 mmol) portion of 1 was dissolved in 10 mL anhydrous, degassed DMF and transferred to the reaction flask. A 50 mL portion of anhydrous, degassed DMF was added to the flask, and the mixture stirred at 70° C. overnight. The mixture warmed to room temperature, the solution filtered to remove salts, and the filtrate concentrated by rotary evaporation. The compound was purified by column chromatography using 1:9 EtOAc/hexanes as the eluent to afford 3.16 g (98%) of 2 as a colorless oil. ¹H NMR (500 MHz, CDCl₃): δ: 10.47 (s, 1H), 8.14 (d, J=9.1 Hz, 1H), 7.29 (d, J=2.8 Hz, 1H), 7.12 (dd, J=9.1 Hz, 2.8 Hz, 1H), 4.19 (q, J=7.1 Hz, 4H), 4.10 (t, J=6.2 Hz, 2H), 2.03 (m, 2H), 1.81 (m, 2H), 1.45 (s, 3H), 1.25 (t, J=7.1 Hz, 6H). ¹³C NMR (500 MHz, CDCl₃): 188.34, 171.85, 163.17, 142.02, 134.15, 127.09, 118.70, 113.52, 68.88, 61.20, 53.06, 31.91, 23.97, 19.79, 13.88. HRMS (ESI MS) m/z: theor: 382.1496 found: 382.1496.

### Diethyl 2-(3-(3-(1-hydroxyethyl)-4-nitrophenoxy)propyl)-2-methylmalonate(3)

To an oven-dried 2-neck round-bottom flask, 240 mL anhydrous, degassed diethyl ether was added and cooled to −78° C. A 4.03 g (21.24 mmol) portion of TiCl₄ was added to the reaction flask followed by slow addition of 2.60 mL (7.79 mmol) of 3M CH₃MgBr in diethyl ether. After 30 minutes of stirring at −78° C., 2.7 g (7.08 mmol) of 2 dissolved in 10 mL diethyl ether was added to the reaction mixture. The solution was stirred for 3 hours and warmed to room temperature. The reaction mixture was poured into 400 mL H₂O and extracted with EtOAc. The organic layers were washed with H₂O and brine, dried over MgSO₄, filtered and concentrated by rotary evaporation. The compound was purified via column chromatography using 1:4 EtOAc/Hexanes as the eluent to afford 2.44 g (87%) of 3 as a pale yellow oil. ¹H NMR (500 MHz, CDCl3): δ: 8.03 (d, J=9.1 Hz, 1H), 7.30 (d, J=2.8 Hz, 1H), 6.82 (dd, J=9.1 Hz, 2.8 Hz, 1H), 5.55 (q, J=6.3 Hz, 1H), 4.19 (q, J=7.1 Hz, 4H), 4.07 (t, J=6.3 Hz, 2H), 2.03 (m, 2H), 1.80 (m, 2H), 1.54 (d, J=6.3 Hz, 3H), 1.45 (s, 3H), 1.25 (t, J=7.1 Hz, 6H). ¹³C NMR (500 MHz, CDCl₃): 172.27, 163.43, 144.99, 140.52, 127.73, 113.52, 112.59, 68.58, 66.07, 61.50, 53.42, 32.27, 24.35, 24.32, 20.10, 14.20. HRMS (ESI MS) m/z: theor: 420.1629 found: 420.1625.

### Diethyl 2-(3-(3-(1-bromoethyl)-4-nitrophenoxy)propyl)-2-methylmalonate (4)

To an oven-dried round-bottom flask, 740 mg (2.82 mmol) of PPh₃ and 470 mg (2.64 mmol) of N-bromosuccinimide were added, the flask evacuated, and refilled with argon 3 times. The flask was cooled to 0° C. and 700 mg (1.76 mmol) of 3 dissolved in 30 mL of THF was added to the reaction mixture. The reaction mixture was stirred for 3 hours while warming to room temperature, and quenched with 20 mL H₂O. The mixture was extracted with EtOAc, the organic layer was washed with H₂O and brine, dried over MgSO₄, filtered, and concentrated by rotary evaporation. The compound was purified by column chromatography using 1:4 EtOAc/Hexanes as the eluent, affording 437 mg (54%) 4 as a pale yellow oil. ¹H NMR (500 MHz, CDCl₃): δ: 7.95 (d, J=9.1 Hz, 1H), 7.31 (d, J=2.7 Hz, 1H), 6.84 (dd, J=9.1 Hz, 2.7 Hz, 1H), 6.00 (q, J=6.8 Hz, 1H), 4.20 (q, J=7.1 Hz, 4H), 4.07 (td, J=6.3 Hz, 1.5 Hz, 2H), 2.05 (m, 5H), 1.82 (m, 2H), 1.46 (s, 3H), 1.26 (t, J=7.1 Hz, 6H). ¹³C NMR (500 MHz, CDCl₃): 172.24, 162.92, 141.05, 140.35, 127.57, 115.75, 113.99, 68.71, 61.52, 53.41, 42.68, 32.29, 27.38, 24.34, 20.11, 14.22. HRMS (ESI MS) m/z: theor: 460.0965 found: 460.0960.

### Diethyl-2-(3-(3-(1-(4-(2,5-dibromothiophen-3-yl)phenoxy)ethyl)-4 nitrophenoxy)-propyl)-2-methylmalonate (5)

To an oven-dried 2-neck round-bottom flask, 207 mg (0.45 mmol) of 4 and 186 mg (1.35 mmol) of potassium bicarbonate were added and the flask evacuated and refilled with argon 3 times. A 165 mg (0.49 mmol) portion of M1 dissolved in 10 mL anhydrous, degassed DMF was added to the flask, followed by addition of 30 mL of anhydrous, degassed DMF. The reaction mixture was stirred overnight at 60° C. and quenched with 5 mL of 1M HCl followed by 30 mL H₂O. The mixture was extracted with EtOAc, the organic layers washed with H₂O and brine, dried over MgSO₄, filtered, and concentrated by rotary evaporation. The compound was purified by column chromatography using dichloromethane as the eluent to afford 287 mg (89%) of 5 as a pale yellow oil. ¹H NMR (500 MHz, CDCl₃): δ: 8.14 (d, J=9.1 Hz, 1H), 7.35 (d, J=8.5 Hz, 2H), 7.21 (d, J=2.4 Hz, 1H), 6.94 (s, 1H), 6.84 (m, 3H), 6.18 (q, J=6.2 Hz, 1H), 4.18 (q, J=7.0 Hz, 4H), 3.99 (m, 2H), 2.00 (m, 2H), 1.76 (m, 2H), 1.70 (d, J=6.2 Hz, 3H), 1.42 (s, 3H), 1.24 (t, J=7.1 Hz, 6H). ¹³C NMR (500 MHz, CDCl₃): 172.23, 163.79, 157.24, 142.90, 141.54, 140.11, 131.73, 129.93, 128.11, 127.12, 115.54, 113.77, 112.56, 111.17, 107.03, 71.98, 68.61, 61.49, 53.39, 32.23, 24.29, 23.68, 20.06, 14.21. HRMS (ESI MS) m/z: theor: 734.0029 found: 734.0029.

P(T3-MS)—O

To an oven-dried 3-neck flask, 198 mg (0.40 mmol) of 5,5′-bis(trimethylstannyl)-2,2′-bithiophene was added, the flask evacuated, and refilled with argon 3 times. A 287 mg (0.40 mmol) portion of 5 dissolved in 10 mL of dry degassed toluene was added to the flask. Under an argon atmosphere, 13 mg (0.012 mmol) of Pd₂(dba)₃ chloroform adduct and 15 mg (0.048 mmol) of P(otolyl) 3 were placed in a vial, dissolved in 15 mL of dry, degassed toluene, and added to the reaction flask. The reaction mixture was stirred at 110° C. for 50 hours, 0.1 mL of 2-(tributylstannyl)thiophene was added as an end-capper, and the mixture stirred overnight. A 0.1 mL portion of 2-bromothiophene was added as an end-capper, stirred for 6 hours, cooled, and precipitated into methanol. The precipitate was filtered and purified by successive Soxlet extractions in methanol, acetone, hexanes, and chloroform. The chloroform fraction was stirred at 40° C. with a spatula tip quantity of the palladium scavenger (diethylammonium diethyldithiocarbamate) for 1 hour, concentrated to <10 mL and precipitated into methanol. The precipitate was filtered and dried at high vacuum to afford 185 mg (68%) of P(T3-MS)—O as a red powder. Mn: 11 kDa, Mw: 21 kDa, D: 1.9 (GPC in THF vs. Polystyrene). Anal. calcd. for C₃₇H₃₅NO₈S₃: C (61.91) H (4.91) N (1.95) S (13.40), Found: C (60.48) H (5.05) N (1.85) S (13.61).

P(T3-MS)—PE

As shown in the reaction scheme in FIG. 14, in an oven-dried round-bottom flask 52 mg of P(T3-MS)—O and 15 mL of a 1M KOH in methanol solution were added. The reaction mixture was stirred at 70° C. overnight, filtered and washed with methanol, and dried to afford 46 mg of P(T3-MS)—PE as a red powder.

Film Preparation

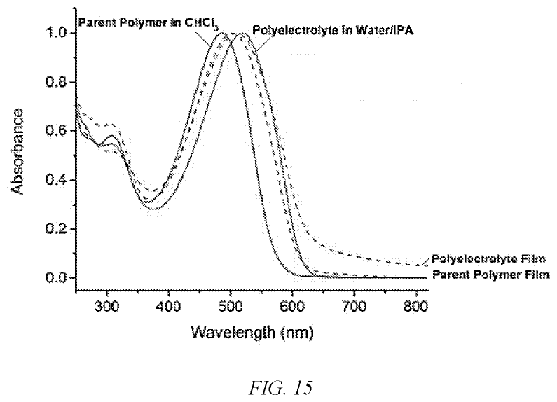

All films were blade coated in ambient air from a 15 mg/mL solution in chloroform or 1:1 H₂O:IPA for P(T3-MS)—O and P(T3-MS)—PE, respectively. Both solutions were stirred at 50° C. overnight prior to coating. The substrate to blade gap was set to 300 μm and the blade speed was set at 7.6 mm/s. The substrate temperature was kept at 60° C. All films were coated to 70*10 nm. For P(T3-MS)—PE films, after 150 minutes irradiation by 365 nm UV light at 5 mW/cm², films were immersed into a warm bath of 1:1 H₂O:IPA on a hot plate at 50° C. and stirred for 1 minute. The films were placed onto the 50° C. hotplate until water evaporated, over a period of approximately 1 minute. UV spectra of the solutions and films are shown if FIG. 15, where P(T3-MS)—PE appears to aggregate in solution as evidenced by a red shift in the spectrum.

GIWAXS

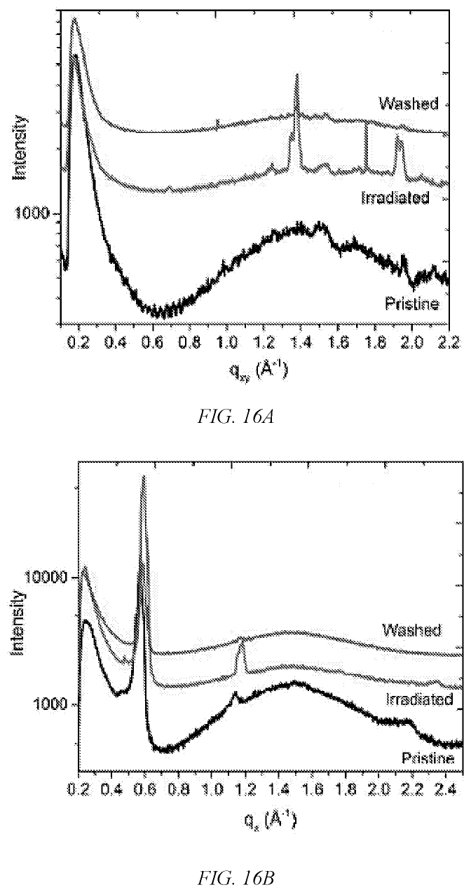

Grazing incidence wide angle X-ray scattering (GIWAXS) was performed at the Stanford synchrotron radiation light source (SSRL) on beamline 11-3. The beam energy was 12.7 keV. The angle of incidence was 0.13°, whereas the nominal critical angle for the films at the used energy is about 0.08°. A LaB6 standard sample was used to calibrate the instrument and the software WxDiff2 version 1.20 was used for data reduction. The sample to detector distance was set at 250 mm. FIGS. 16A and 16B shows offset 1D line cuts in the qxy and qz directions, respectively, for P(T3-MS)—PE pristine, irradiated, and irradiated and washed samples.

N1s, K2p, and S2p XPS Data of P(T3-MS)—PE

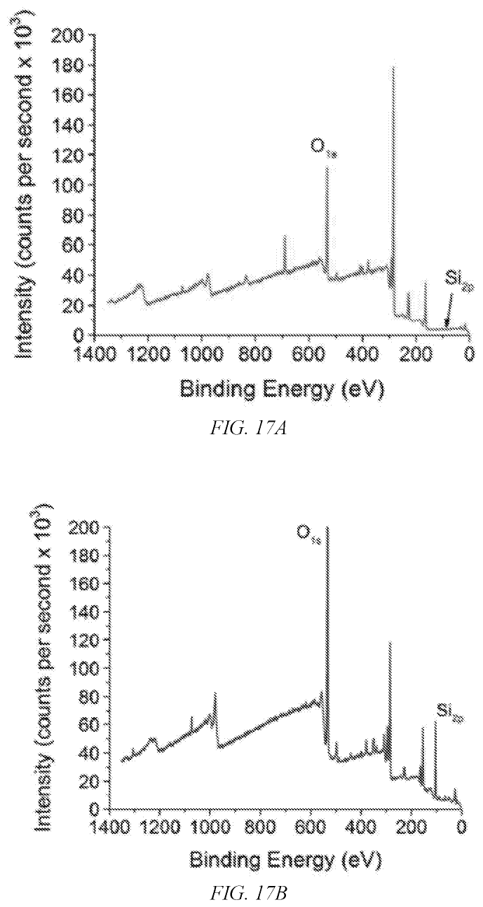

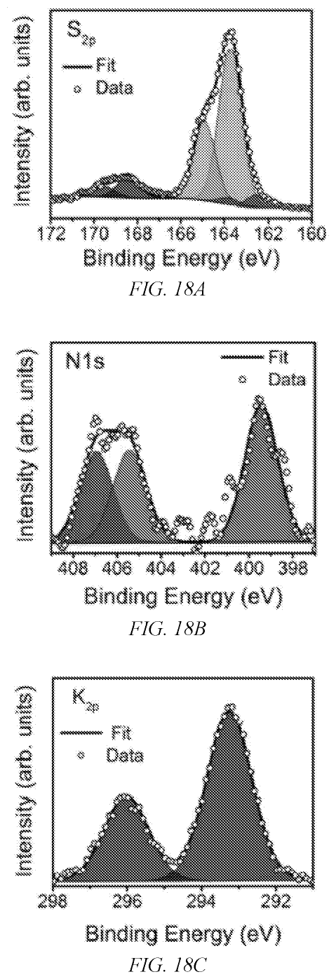

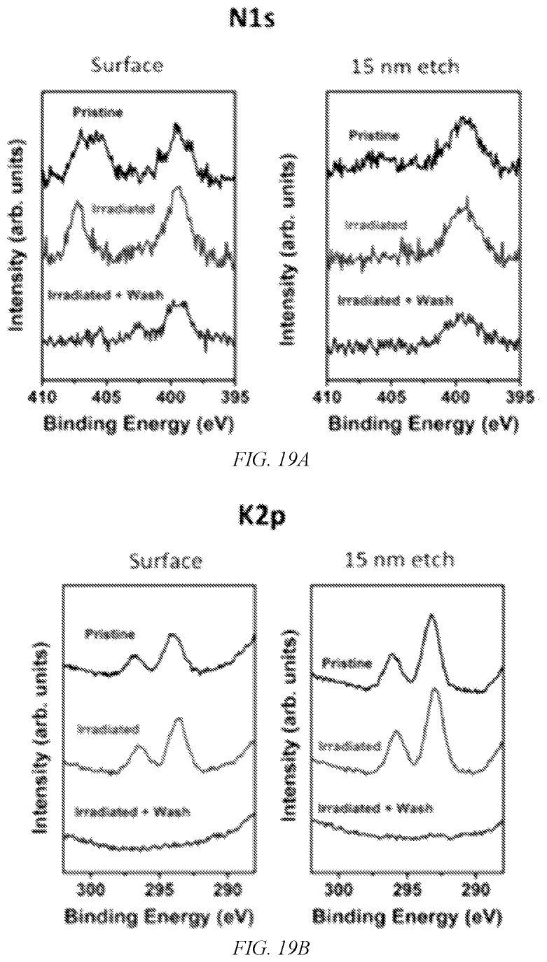

X-ray photoelectron spectroscopy experiments were performed on dried polymer films using a Thermo K-Alpha spectrometer equipped with a monochromated Aluminum K-α x-ray source (1486 eV) and a hemispherical 180° detector. The x-ray spot size used for all samples was 400 μm with a charge compensating flood gun to eliminate sample charging. Survey scans were performed with 1 eV binding energy resolution and 200 eV pass energy Elemental scans with 0.1 eV resolution were performed for N1s (392-410 eV), K2p (287-305 eV), and S²p (157-175 eV) electron binding energies. Depth profiling experiments were performed to analyze chemical makeup of the polymer films throughout their thickness. An argon ion gun was used to etch the polymer film using energy of 1,000 eV at medium current for 40 seconds. The raster size used was 1 mm. After each etching step, survey scans and high-resolution elemental scans were performed as above. Depth profiles were performed through the thickness of the film determined by a large growth of O1s and Si 2p intensity, as shown in FIGS. 17A and 17B. XPS spectra were analyzed and fitted using CasaXPS software in order to determine N:S and K:S atomic percent ratios shown in FIGS. 8A and 8B. Integrated areas were calculated according to the following equation:

$$at \% = \frac{{A}_{rel}}{K {E}^{0.6} ( R S F )}$$

Where Aᵣₑₗ is the integrated area for Ach XPS peak, KE is the kinetic energy, and RSF is the relative sensitivity factor for the element (S:1.68, N:18, and K:3.97). Example fits for the S2p, N1s, and K2p peaks measured on the surface of the P(T3-MS)—PE films are shown in FIGS. 18A-18C. Surface and etched XPS film spectra are shown in FIGS. 19A and 19B for N 1s and K 2p, respectively, for the pristine, irradiated, and washed films.

OFET Device Preparation and Measurements

Bottom-Gate Bottom-Contact OFETs were fabricated on a heavily n-doped silicon wafer <100> as the gate electrode with a 300 nm thick layer of thermally grown SiO₂ as the gate dielectric. The capacitances of the dielectric layers were measured using an Agilent 4284A Precision LCR Meter. The SiO₂ dielectric has a capacitance of ca. 1.08×104 Fm². Au source and drain contacts (50 nm of Au contacts with 3 nm of Cr as the adhesion layer) with fixed channel dimensions (50 μm in length and 2 mm in width) were deposited via E-beam using a photolithography lift-off process. Prior to deposition of polymer semiconductors, the devices were cleaned in acetone for 30 min and subsequently rinsed sequentially with acetone, methanol and isopropanol. The SiO₂ surface was pretreated by UV/ozone for 30 min for cleaning purposes. The devices were cleaned under a flow of nitrogen. Polymer solutions were then blade-coated onto substrates in ambient condition, and then dried by vacuum oven at 100° C. for 24 hours before tested.

All OFET characterizations were performed using a probe station inside a nitrogen atmosphere glovebox using an Agilent 4155C semiconductor parameter analyzer. The FET mobilities were calculated from the saturation regime in the transfer plots of gate voltage (V_{G}) versus source-drain current (I_{SD}) by extracting the slope of the linear range of V_{G} vs. I_{SD}^{1/2} plot and using the following equation:

$$\frac{\partial {I}_{SD}^{1 / 2}}{\partial {V}_{G}} = {( {μ}_{e} {C}_{ox} \frac{W}{2 L} )}^{1 / 2}$$

scanning from 40 to −80 V (for BG/BC OFETs) in the transfer plot; Cₒₓ is the capacitance per unit area of the gate dielectric layer, W and L refer to the channel length and width; μₑ represents the electron field-effect mobility in the saturation regime (cm²V⁻¹s⁻¹).

In this study, the threshold voltage, Vₜₕ, was calculated by extrapolating V_{T}=V_{G} at I_{SD}=0 in the V_{G} vs. I_{SD}^{1/2} curve. Current on/off ratio (I_{ON/OFF}) was determined through dividing maximum I_{SD} (I_{ON}) by the minimum I_{SD} at about V_{G} in the range of −80 to 40 V (I_{OFF}). Temperature was increased to ˜100° C. during the drying process, therefore, no thermal annealed was operated in the fabrication process, which typically is needed in OFET fabrication process to reduce residual solvents. These parameters are tabulated below.

TABLE 1
OFET Device Metrics

| | Mobility μₕ | | |
|---|---|---|---|
| Polymer | (cm² V⁻¹ s⁻¹) | Vₜₕ (V) | I_{On/Off} |
| P(T3-MS) Pristine | −O 8.08 ± 0.91 × 10⁻⁵ | −18.9 ± 4.3 | 10³ |
| P(T3-MS)-O | 3.72 ± 0.29 × 10⁻⁵ | −19.6 ± 0.7 | 10³ |
| Irradiated + Washed | | | |
| P(T3-MS)-PE | 2.50 ± 0.09 × 10⁻⁴ | 45.4 ± 2.3 | 10¹ |
| Pristine | | | |
| P(T3-MS)-PE | 6.82 ± 0.32 × 10⁻⁵ | 31.4± 2.5 | 10¹ |
| Irradiated + Washed | | | |

It should be understood that the examples and embodiments described herein are for illustrative purposes only and that various modifications or changes in light thereof will be suggested to persons skilled in the art and are to be included within the spirit and purview of this application.

We claim:

1. A multistage side-chain conjugated polymer (CP), comprising a conjugated backbone, said conjugated backbone comprising a multiplicity of at least one repeating unit, where at least one of the repeating units comprises a conjugated backbone portion and a multistage side-chain, the multistage side-chain having one or more multiple responsive functionalities and comprising:
at least one photo-cleavable portion comprising a photolytically labile functionality, or at least one thermal-cleavable portion comprising a thermally labile functionality;
at least one first linker comprising at least one bond between the backbone portion and the photo-cleavable portion, or thermal-cleavable portion;
at least one chemically activatable solubilizing portion comprising an activatable functionality capable of undergoing a chemical reaction to provide an aqueous solubilizing functionality bound to an activated multistage side-chain, wherein the aqueous solubilizing functionality is the photolytically labile functionality, the thermally labile functionality, or a separate functionality; and
at least one second linker comprising at least one bond between the solubilizing portion and the cleavable portion providing the aqueous solubilizing functionality is not the photolytically labile, or thermally labile functionality, whereby the multistage side-chain CP is sequentially:
prepared in an organic solution comprising at least one organic solvent;
converted to an aqueous soluble activated multistage side-chain CP, and
photolytically cleaved or thermally cleaved to an insoluble core CP comprising the conjugated backbone portion.

2. The multistage side-chain CP according to claim 1, wherein the multistage side-chain CP is a homopolymer.

3. The multistage side-chain CP according to claim 1, wherein the multistage side-chain CP is a copolymer comprising at least one first repeating unit, wherein the first repeating unit is the repeating unit comprises the conjugated backbone portion and the multistage side-chain and at least one second repeating unit comprising a conjugated backbone portion absent the multistage side-chain.

4. The multistage side-chain CP according to claim 3, wherein the copolymer is a regular copolymer of the structure (AB)ₙ, (AₓB)ₙ where x is 2 to 6, (AₓB_{y}) where x and y are independently 2 to 6; (AₓB_{y}AₓC_{z})ₙ or (AₓB_{y}C_{z}B_{y}Aₓ)ₙ, where x, y, and z are independently 1 to 6 and 2n, n(x+1), n(x+y), n(2x+y+z), or n(2x+2y+z), is 10 to 100,000.

5. The multistage side-chain CP according to claim 3, wherein the copolymer is a random copolymer; or random [(A)ₓ(B)_{y}]ₙ where x and y are independently on average 1 to 10 or [(A)ₓ(B)_{y}(C)_{z}]ₙ where x, y, and z are independently 1 to 10, and n(x+y) or n(x+y+z) is 10 to 100,000.

6. The multistage side-chain CP according to claim 1, wherein the repeating units comprise one or more unsubstituted or substituted backbone portions selected from: 3,4-(1,2-phenylene)-dioxytellurophene; 3,4-(1,2-vinylene)-dioxytelurophene; 3,4-diaminotelurophene; 3,4-dicyanotelurophene; 3,4-diethenyloxytelurophene; 3,4-diformyloxytelurophene; 3,4-diphenoxytelurophene; benzothiadiazoles; telurophene-3,4-dicarboxylic acid; [1,2,5]oxadiazolo [3,4-c]pyridine; [1,2,5]thiadiazolo[3,4-c]pyridine; [1,2,5]thiadiazolo[3,4-g]quinoxaline; 1,3,4-oxadiazole; 1,3,4-thiadiazole; 1,3,4-triazole; 2,2′-bithiazole; 3,4-(1,2-phenylene)dioxyfuran; 3,4-(1,2-phenylene)dioxypyrrole; 3,4-(1,2-phenylene)dioxyselenophene; 3,4-(1,2-phenylene)dioxythiophene; 3,4-(1,2-vinylene)-dioxyfuran; 3,4-(1,2-vinylene)dioxypyrrole; 3,4-(1,2-vinylene)dioxyselenophene; 3,4-(1,2-vinylene)dioxythiophene; 3,4-alkylenedioxyfuran; 3,4-alkylenedioxypyrrole; 3,4-alkylenedioxyselenophene; 3,4-alkylenedioxytelurophene; 3,4-alkylenedioxythiophene; 3,4-dialkyfuran; 3,4-dialkypyrrole; 3,4-dialkyselenophene; 3,4-dialkythiophene; 3,4-diaminofuran; 3,4-diaminopyrrole; 3,4-diaminoselenophene; 3,4-diaminothiophene; 3,4-dicyanofuran; 3,4-dicyanopyrrole; 3,4-dicyanoselenophene; 3,4-dicyanothiophene; 3,4-diethenyloxyfuran; 3,4-diethenyloxypyrrole; 3,4-diethenyloxyselenophene; 3,4-diethenyloxythiophene; 3,4-diformyloxyfuran; 3,4-diformyloxypyrrole; 3,4-diformyloxyselenophene; 3,4-diformyloxythiophene; 3,4-dihalofuran; 3,4-dihalopyrrole; 3,4-dihaloselenophene; 3,4-dihalotelurophene; 3,4-dihalotelurophene; 3,4-dihalothiophene; 3,4-dihalothiophene; 3,4-dihydroxyfuran; 3,4-dihydroxypyrrole; 3,4-dihydroxyselenophene; 3,4-dihydroxytelurophene; 3,4-dihydroxythiophene; 3,4-dioxyfuran; 3,4-dioxypyrrole; 3,4-dioxyselenophene; 3,4-dioxytelurophene; 3,4-dioxythiophene; 3,4-diphenoxyfuran; 3,4-diphenoxypyrrole; 3,4-diphenoxyselenophene; 3,4-diphenoxythiophene; 3,5-dialkoxy-dithieno[3,2-b:2′,3′-d]thiophene; 3,6-dialkoxythieno[3,2-b]thiophene; 4,4′-bis(alkyl)-[6,6′-bithieno[3,2-b]pyrrolylidene]-5,5′(4H,4′H)-dione; 4-dicyanomethylenecyclopentadithiolene; benzo[1,2-b:6,5-b′]dithiophene-4,5-dione; anthracene; benzo[1,2-c;4,5-c′]bis[1,2,5]-thiadiazole; benzo[c][1,2,5]oxadiazole; benzo[c]thiophene; benzo[d][1,2,3]triazole; benzobisthiadiazole; benzothiadiazole; carbazole; cyanovinylene; cyclopentadithiophene-4-one; dicyanovinylene; dithieno[3,2-b:2′,3′-d]thiophene; ethene; fluorene; furan; furan-3,4-dicarboxylic acid; indigo; isoindigo; naphthalene; napthalenediimide; perylenediimide; phenanthrene; phenanthrene-9,10-dione; phenylene; pyrazine; pyrazinoquinoxaline; pyrene; pyrido[3,4-b]pyrazine; pyrrole; pyrrolo[3,4-c]pyrrole-1,4-dione; quinoline; quinoxaline; selenophene; selenophene-3,4-dicarboxylic acid; telurophene; thiadiazoloquinoxaline; thiadiazolothienopyrazine; thiazolo[5,4-d]thiazole; thiazolo[5,4-d]thiazole; thieno[3,2-b]thiophene; thieno[3,4-b]pyrazine; thieno[3,4-b]pyrazine; thienopyrazine; thienothiadiazole; thienothiadiazole; thiophene; thiophene-3,4-dicarboxylic acid; or any fuse or plurally fused combination thereof.

7. The multistage side-chain CP according to claim 6, wherein the substituent backbone portions can be singularly or plurally substituted independently with C₁-C₃₀ alkyl, C₂-C₃₀ alkenyl, C₂-C₃₀ alkynyl, C₆-C₁₄ aryl, C₇-C₃₀ arylalkyl, C₈-C₃₀ arylalkenyl, C₈-C₃₀ arylalkynyl, hydroxy, C₁-C₃₀ alkoxy, C₆-C₁₄ aryloxy, C₇-C₃₀ arylalkyloxy, C₂-C₃₀ alkenyloxy, C₂-C₃₀ alkynyloxy, C₈-C₃₀ arylalkenyloxy, C₈-C₃₀ arylalkynyloxy, CO₂H, C₂-C₃₀ alkylester, C₇-C₁₅ arylester, C₈-C₃₀ alkylarylester, C₃-C₃₀ alkenylester, C₃-C₃₀ alkynylester, NH₂, C₁-C₃₀ alkylamino, C₆-C₁₄ arylamino, C₇-C₃₀ (arylalkyl)amino, C₂-C₃₀ alkenylamino, C₂-C₃₀ alkynylamino, C₈-C₃₀ (arylalkenyl)amino, C₈-C₃ (arylalkynyl)amino, C₂-C₃₀ dialkylamino, C₁₂-C₂₈ diarylamino, C₄-C₃₀ dialkenylamino, C₄-C₃₀ dialkynylamino, C₇-C₃₀ aryl(alkyl)amino, C₇-C₃₀ di(arylalkyl)amino, C₈-C₃₀ alkyl(arylalkyl)amino, C₁₅-C₃₀ aryl(arylalkyl)amino, C₈-C₃₀ alkenyl(aryl)amino, C₈-C₃₀ alkynyl(aryl)amino, C(O)NH₂ (amido), C₂-C₃₀ alkylamido, C₇-C₁₄ arylamido, C₈-C₃₀ (arylalkyl)amido, C₂-C₃₀ dialkylamido, C₁₂-C₂₈ diarylamido, C₈-C₃₀ aryl(alkyl)amido, C₁₅-C₃₀ di(arylalkyl)amido, C₉-C₃₀ alkyl(arylalkyl)amido, C₁₆-C₃₀ aryl(arylalkyl)amido, thiol, C₁-C₃₀ hydroxyalkyl, C₆-C₁₄ hydroxyaryl, C₇-C₃₀ hydroxyarylalkyl, C₃-C₃₀ hydroxyalkenyl, C₃-C₃ hydroxyalkynyl, C₈-C₃₀ hydroxyarylalkenyl, C₈-C₃₀ hydroxyarylalkynyl, C₃-C₃₀ polyether, C₃-C₃₀ polyetherester, C₃-C₃₀ polyester, C₃-C₃₀ polyamino, C₃-C₃₀ polyaminoamido, C₃-C₃₀ polyaminoether, C₃-C₃₀ polyaminoester, C₃-C₃₀ polyamidoester, C₃-C₃₀alkylsulfonic acid, C₃-C₃₀alkylsulfonate salt, C₁-C₃₀ carboxylate salt, thiocarboxylate salt, dithiocarboxylate salt or C₃-C₃₀alkylC₁-C₄ trialkyammonium salt, wherein alkyl is independently straight, branched, multiply branched, cyclic, or polycyclic, where the cyclic and/or the polycyclic is unsubstituted, substituted, or polysubstituted, alkenyl is monoene, diene, or polyene where the diene and/or the polyene is non-conjugated, conjugated, or a combination thereof and is straight, branched, multiply branched, cyclic, or polycyclic and is terminal or internal and is unsubstituted or substituted at any carbon where enes are E or Z isomers or mixture thereof, alkynes can be mono-yne, non-conjugated or conjugated poly-yne, terminal or internal, substituted at any carbon, aryl groups can be cyclic or polycyclic and unfused or fused, and where heteroatom containing substituents have one or more heteroatoms.

8. The multistage side-chain CP according to claim 1, wherein the photolytically labile functionality comprises an o-nitrobenzyl group, a 9-phenylthioxanthyl group, a benzoin group, a (2-hydroxy-3-naphthylvinyl)-di-isopropylsilyl group, a thiochromone S,S dioxide group, a 6-Bromo-4-(1,2-dihydroxyethyl)-7-hydroxycoumarin group, a 4H-benzo[d][1,3]dioxine-2-yl group, or a 4,4-bis-phenyl-4H-benzo[d][1,3]dioxine-2-yl group.

9. The multistage side-chain CP according to claim 1, wherein the thermally labile functionality comprises a trimethylalkyl ammonium hydroxide, trimethylalkyl ammonium alkoxide, a Diel-Alder adduct, a beta-carbonyl ester, or a carbamate.

10. The multistage side-chain CP according to claim 1, wherein the activatable functionality comprises an ester, silylester, sulfate ester, phosphate ester, amine, or phosphine.

11. The multistage side-chain CP according to claim 1, wherein the first and/or the second linker comprises a single bond, a oxygen, an unsubstituted or substituted amine, an unsubstituted or substituted methylene, an unsubstituted or substituted alkylene, an unsubstituted or substituted alkenylene, or an unsubstituted or substituted phenylene.

12. The multistage side-chain CP according to claim 1, wherein the structure is:

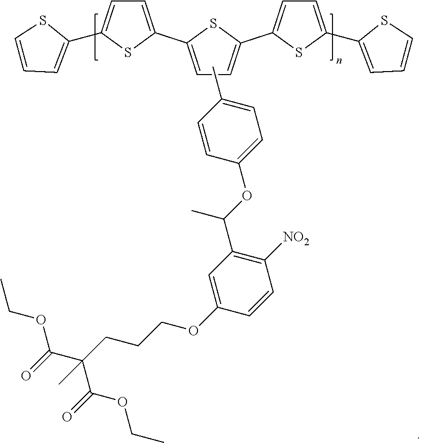

13. The multistage side-chain CP according to claim 1, wherein the structure is:

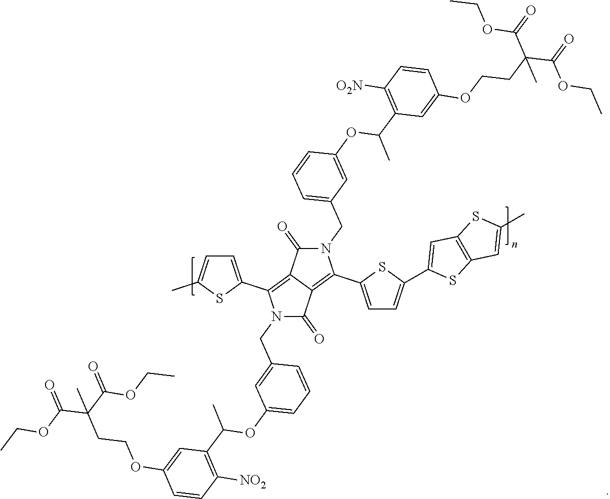

14. A method of preparing a multistage side-chain CP according to claim 1, comprising:
providing a multiplicity of monomers or conjugated oligomers comprising an ene, diene, arylene, or heteroarylene and leaving groups, wherein at least one of the monomers comprises a multistage side-chain; and
polymerizing the multiplicity of monomers by Stille, Suzuki, Kumada, Hiyama, Negishi, or direct arylation to the multistage side-chain CP.

15. A method of preparing an insoluble film of a CP, comprising:
providing a multistage side-chain CP according to claim 1 in an organic solution;
adding a chemical agent to convert the multistage side-chain CP to an aqueous soluble activated multistage side-chain CP;
dissolving the aqueous soluble activated multistage side-chain CP in a solvent comprising water to form an activated multistage side-chain CP solution;
depositing the activated multistage side-chain CP solution as a film on a substrate;
photolytically cleaving or thermally cleaving the photolytically labile functionality or thermally labile functionality to separate the core CP from a soluble multistage side-chain residue or a volatile multistage side-chain residue; and
removing the soluble multistage side-chain residue or the volatile multistage side-chain residue and leaving the core CP as a CP film on the substrate.

16. The method of claim 15, wherein depositing is selected from slot-die coating, gravure coating, knife-over-edge coating, off-set coating, spray coating, ink jet printing, pad printing, and screen printing.

17. The method of claim 15, wherein the CP film on the substrate is of an organic electronic device.

18. The method of claim 17, wherein the organic electronic device is an organic photovoltaic device, an organic field effect transistor, an electrochromic device, an electrochemical charge storage device, an organic photodetector, a chemical sensor, a bio-sensor, an organic electrochemical transistor, an organic light emitting diode, or an organic light emitting electrochemical cell.
